(19) United States
(12) Patent Application Publication
(10) Pub. No.: US 2023/0379582 A1
(43) Pub. Date: Nov. 23, 2023

(54) Camera Module and Electronic Device

(71) Applicant: Honor Device Co., Ltd., Shenzhen (CN)

(72) Inventors: Xing Wang, Shenzhen (CN); Shuai Yuan, Shenzhen (CN)

(21) Appl. No.: 18/245,064

(22) PCT Filed: Aug. 29, 2022
(86) PCT No.: PCT/CN2022/115548

§ 371 Date: Mar. 13, 2023

(30) Foreign Application Priority Data
Sep. 3, 2021 (CN) 202111031640.5

(51) Int. Cl. H04N 23/68; H04N 23/54; H04N 23/57

(52) U.S. Cl. CPC H04N 23/685; H04N 23/54; H04N 23/57

(57) ABSTRACT

An electronic device includes a camera module, and the camera module includes a support, an optical lens, a first circuit board, a second circuit board, an electrical connection apparatus, and an optical image stabilization apparatus. The optical lens is located in the support; the first circuit board is fixed to the support; the second circuit board is stacked with the first circuit board, and an image sensor is disposed on the second circuit board, and a light sensing surface of the image sensor is opposite to a light emitting surface of the optical lens; the electrical connection apparatus electrically connects the second circuit board to the first circuit board; and the optical image stabilization apparatus is configured to drive the second circuit board to move, relative to the first circuit board, in a plane in which the second circuit board is located.

### CROSS-REFERENCE TO RELATED APPLICATIONS

This application is a U.S. National Stage of International Application No. PCT/CN2022/115548 filed on Aug. 29, 2022, which claims priority to Chinese Patent Application No. 202111031640.5, filed with the China National Intellectual Property Administration on Sep. 3, 2021, both of which are incorporated herein by reference in their entireties.

### TECHNICAL FIELD

This application relates to the field of electronic device technologies, and in particular, to a camera module and an electronic device.

### BACKGROUND

Currently, a photo or video photographed by an electronic device such as a mobile phone, a tablet computer, and a personal computer (PC) in a photographing process sometimes becomes blurred, that is, the photographed picture is not clear enough, and ghosting or blurring occurs. This occurs partly because a small jitter occurs on a handheld electronic device during photographing.

To improve photographing clarity, currently, a camera module of a high-end electronic device is integrated with an optical image stabilization (OIS) apparatus. The OIS apparatus is configured to drive a lens or an image sensor to tilt or move in a reverse direction of a jitter direction of the electronic device, so as to compensate for a jitter displacement amount, thereby improving picture photographing clarity. Compared with the solution in which the lens is driven to tilt or move, the solution in which the image sensor is driven to move has less load, and a volume of the OIS apparatus may be made smaller. However, because a circuit board in which the image sensor is located is relatively large, when the image sensor is driven to move to implement OIS, an occupied space when the circuit board is active is relatively large, thereby causing a relatively large occupation area of a camera module, which is not conducive to mounting in an electronic device with a limited space.

### SUMMARY

Embodiments of this application provide a camera module and an electronic device, so as to ensure photographing quality of the camera module and reduce an occupation area of the camera module.

To achieve the foregoing objective, the following technical solutions are used in the embodiments of this application:

According to a first aspect, some embodiments of this application provide a camera module, where the camera module includes a support, an optical lens, a first circuit board, a second circuit board, an electrical connection apparatus, and an optical image stabilization apparatus. The optical lens is located in the support. The first circuit board is fixed to the support. The second circuit board is stacked with the first circuit board, an image sensor is disposed on the second circuit board, and a light sensing surface of the image sensor is opposite to a light emitting surface of the optical lens. The electrical connection apparatus electrically connects the second circuit board to the first circuit board. The optical image stabilization apparatus is configured to drive the second circuit board to move, relative to the first circuit board, in a plane in which the second circuit board is located, so as to implement optical image stabilization.

In the camera module provided in this embodiment of this application, the first circuit board is fixed to the support, the image sensor is disposed on the second circuit board, and the second circuit board is driven by using the optical image stabilization apparatus to move, relative to the first circuit board, in the plane in which the second circuit board is located, thereby implementing OIS. On this basis, because the circuit board of the camera module includes the first circuit board and the second circuit board, electronic components in the camera module may be distributed on the first circuit board and the second circuit board, so that an area of the second circuit board used to carry the image sensor can be reduced, and an occupied space when the second circuit board is active can be reduced. On this basis, because the second circuit board is stacked with the first circuit board, an occupation area and volume of the camera module may be reduced, so as to facilitate mounting in an electronic device with a limited space.

In a possible implementation of the first aspect, the electrical connection apparatus includes a conductive plate and a conductive contact member. The conductive plate is disposed on the first circuit board and electrically connected to the first circuit board. The conductive contact member is disposed on the second circuit board and electrically connected to the second circuit board. The conductive contact member is electrically connected to the conductive plate, and when the second circuit board moves, relative to the first circuit board, in the plane in which the second circuit board is located, the conductive contact member moves on the conductive plate. In this way, image information and an image stabilization compensation amount can be transmitted between the first circuit board and the second circuit board through cooperation between the conductive plate and the conductive contact member. The electrical connection apparatus does not affect movement of the second circuit board, relative to the first circuit board, in the plane in which the second circuit board is located, and a volume of the electrical connection apparatus is small, which helps reduce a distance between the second circuit board and the first circuit board. In addition, when implementing the electrical connection between the two circuit boards, the electrical connection apparatus supports the second circuit board to a specific height from the first circuit board, so as to prevent the second circuit board from directly contacting the first circuit board and causing a short circuit.

In a possible implementation of the first aspect, the conductive contact member is not rollable relative to the second circuit board. Optionally, the conductive contact member is fixed to the second circuit board. When the second circuit board moves, relative to the first circuit board, in the plane in which the second circuit board is located, the conductive contact member slides on the conductive plate. A sliding friction pair is formed between the conductive contact member and the conductive plate. A composition structure of the electrical connection apparatus is simple, and costs are relatively low.

In a possible implementation of the first aspect, the conductive contact member is in a hemispherical shape, and a spherical surface of the conductive contact member is electrically connected to the conductive plate. In this way, a contact area between the conductive contact member and the conductive plate is relatively small. In a process in which the second circuit board moves relative to the first circuit board, resistance for the second circuit board is relatively small, which helps reduce a volume and costs of the optical image stabilization apparatus.

In a possible implementation of the first aspect, the conductive contact member includes a conductive ball. The conductive ball is rollable relative to the second circuit board, the conductive ball is electrically connected to the second circuit board, and the conductive contact member is electrically connected to the conductive plate by using the conductive ball. When the second circuit board moves, relative to the first circuit board, in the plane in which the second circuit board is located, the conductive ball rolls on the conductive plate. In this way, a rolling friction pair is formed between the conductive contact member and the conductive plate, and wear of the rolling friction pair is relatively small, so that service life of the electrical connection apparatus can be prolonged.

In a possible implementation of the first aspect, the conductive contact member further includes a holder. The holder is made of a conductive material. The holder has opposite top and bottom surfaces. The holder is fixed to the second circuit board by using the top surface, and is electrically connected to the second circuit board, so that the bottom surface of the holder is back to back with the second circuit board. The holder is provided with a receptacle hole that runs through the bottom surface. The conductive ball is placed in the receptacle hole and electrically connected to the holder. A diameter of the conductive ball is greater than a diameter of an opening at one end of the receptacle hole that runs through the bottom surface, and a part of the conductive ball projects from the opening at one end of the receptacle hole that runs through the bottom surface. In this way, the conductive ball is electrically connected to the second circuit board by using the holder, a connection manner is simple, and operation is convenient.

In a possible implementation of the first aspect, the receptacle hole further runs through the top surface of the holder. From one end that runs through the top surface to one end that runs through the bottom surface, an aperture of the receptacle hole gradually decreases, so that the receptacle hole is funnel-shaped. A diameter of the conductive ball is less than a diameter of an opening at one end of the receptacle hole that runs through the top surface. In this way, the conductive ball may be mounted in the receptacle hole by using the opening at one end of the receptacle hole that runs through the top surface, and stopping and limiting are performed by using the second circuit board. Mounting of the conductive ball is easy and efficient. In some other embodiments, the receptacle hole may not run through the top surface of the holder.

In a possible implementation of the first aspect, the holder is made of an insulating material, and a pad is disposed on the second circuit board. The pad is opposite to the receptacle hole. The conductive ball is disposed in the receptacle hole and electrically connected to the pad, so as to implement electrical connection between the conductive ball and the second circuit board. On this basis, holders of a plurality of conductive contact members may be connected together and formed integrally. This helps reduce difficulty and costs of making the holder.

In a possible implementation of the first aspect, a first elastic member is disposed between the conductive plate and the first circuit board, and the first elastic member exerts an elastic force on the conductive plate that points to the conductive contact member, so that the conductive plate is in contact with the conductive contact member; and/or a second elastic member is disposed between the conductive contact member and the second circuit board, and the second elastic member exerts an elastic force on the conductive contact member that points to the conductive plate, so that the conductive contact member is in contact with the conductive plate. In this way, the first elastic member and/or the second elastic member may be used to ensure contact reliability between the conductive contact member and the conductive plate.

In a possible implementation of the first aspect, the camera module further includes a limiting apparatus. The limiting apparatus allows the second circuit board to move, relative to the first circuit board, in the plane in which the second circuit board is located, and prevents the second circuit board from moving in a direction away from the first circuit board. In this way, OIS drive stability can be ensured. The limiting apparatus that can achieve this objective has a plurality of structural forms, which are not specifically limited in this embodiment of this application.

In a possible implementation of the first aspect, the limiting apparatus includes at least one third elastic member. The third elastic member exerts an elastic force on the second circuit board that points to the first circuit board, so as to prevent the second circuit board from moving in a direction away from the first circuit board. In this way, when wear occurs due to relative motion between the second circuit board and the first circuit board, under the action of the elastic force, the second circuit board may be driven to move towards a direction close to the first circuit board by a specific distance, so as to compensate for the wear amount, thereby extending service life of a photosensitive component.

In a possible implementation of the first aspect, the third elastic member includes a first end and a second end. The first end is relatively fixed to the first circuit board, the second end is relatively fixed to the second circuit board, and a part of the third elastic member that is connected between the first end and the second end can be deformed in any direction parallel to the second circuit board, so that the second circuit board can move, relative to the first circuit board, in the plane in which the second circuit board is located.

In a possible implementation of the first aspect, a part of the third elastic member that is connected between the first end and the second end includes a first n-type extension section and a second n-type extension section. An arch direction of the first n-type extension section is perpendicular to an arch direction of the second n-type extension section, and both the arch direction of the first n-type extension section and the arch direction of the second n-type extension section are parallel to the second circuit board. A structure of the third elastic member is simple and easy to implement.

In a possible implementation of the first aspect, there are a plurality of third elastic members, and the plurality of third elastic members are uniformly disposed around a circumference of the second circuit board. In this way, limiting stability can be ensured.

In a possible implementation of the first aspect, the second circuit board is located on a light emitting side of the optical lens, the first circuit board and the optical lens are located on a same side of the second circuit board, and the image sensor is disposed on a surface of the second circuit board close to the first circuit board. In this way, the image sensor may be accommodated by using a gap between the first circuit board and the second circuit board, which helps reduce a height of the camera module. On this basis, the electrical connection apparatus between the first circuit board and the second circuit board is disposed around the image sensor.

In a possible implementation of the first aspect, the first circuit board is located between the second circuit board and the optical lens, and an optical port is disposed in a region of the first circuit board that is opposite to a light emitting surface of the optical lens. In this way, the height of the camera module may be reduced to some extent, and an optical path is prevented from being affected by the first circuit board.

In a possible implementation of the first aspect, an avoidance port is disposed on the first circuit board, and the optical lens is located in the avoidance port. In this way, a location of the first circuit board is further moved upward, and the height of the camera module can be further reduced.

In a possible implementation of the first aspect, the second circuit board is located on a light emitting side of the optical lens, the first circuit board is located on a side of the second circuit board away from the optical lens, and the image sensor is disposed on a surface of the second circuit board away from the first circuit board. In this way, the electrical connection apparatus between the first circuit board and the second circuit board and the image sensor are stacked in a height direction of the camera module. This helps reduce a setting area of the first circuit board and the second circuit board, and further reduces an occupation area and a volume of the camera module.

In a possible implementation of the first aspect, an area of the second circuit board is less than an area of the first circuit board, and an orthographic projection of the second circuit board on the first circuit board is located in the first circuit board. In this way, on a premise that a sum of the areas of the first circuit board and the second circuit board is definite, when the area of the second circuit board is relatively small, an occupied space during movement is relatively small, and the occupation area of the camera module can be further reduced, so as to be mounted in an electronic device with a limited space.

In a possible implementation of the first aspect, the optical image stabilization apparatus includes a first coil and a first magnet. The first coil is disposed on the second circuit board, the first magnet is disposed on the first circuit board, the first coil cooperates with the first magnet to generate a Lorenz force parallel to the second circuit board, and the Lorenz force is used to drive the second circuit board to move, relative to the first circuit board, in the plane in which the second circuit board is located. The structure is simple and is easy to implement.

In a possible implementation of the first aspect, the second circuit board is square or rectangular, and the first coil is disposed at a corner part of the second circuit board. The first magnet is opposite to the first coil. A relatively small quantity of electronic components are disposed at the corner part of the circuit board. Therefore, a coil is disposed at the corner part, so that utilization of the second circuit board can be improved, and a setting area of the second circuit board can be reduced.

In a possible implementation of the first aspect, the camera module further includes an image stabilization drive chip. The image stabilization drive chip is disposed on the second circuit board, the image stabilization drive chip is electrically connected to the first coil, and the image stabilization drive chip is further electrically connected to the first circuit board by using the electrical connection apparatus.

In a possible implementation of the first aspect, the camera module further includes an automatic focusing apparatus. The automatic focusing apparatus is connected between the optical lens and the support, and the automatic focusing apparatus is configured to drive the optical lens to move relative to the support in an optical axis direction of the optical lens, so as to implement automatic focusing. In this way, the camera module integrates an optical image stabilization and automatic focusing function, which can improve photographing clarity of the camera module.

In a possible implementation of the first aspect, the automatic focusing apparatus includes a second coil and a second magnet. The second coil is relatively fixed to the optical lens, the second magnet is relatively fixed to the support, and the second coil cooperates with the second magnet to generate a Lorenz force in the optical axis direction of the optical lens. The Lorenz force is used to drive the optical lens to move relative to the support in the optical axis direction of the optical lens. The structure is simple and is easy to implement.

In a possible implementation of the first aspect, the camera module further includes a focusing drive chip. The focusing drive chip is disposed on the first circuit board, and the focusing drive chip is electrically connected to the second coil.

According to a second aspect, some embodiments of this application provide an electronic device, where the electronic device includes the camera module described in any one of the foregoing technical solutions.

Because the electronic device provided in this embodiment of this application includes the camera module described in any one of the foregoing technical solutions, the two can resolve a same technical problem and achieve a same effect.

In a possible implementation of the second aspect, the electronic device further includes a housing and a main board, the main board and the camera module are located in the housing, a first circuit board of the camera module is electrically connected to the main board, a light transmission window is disposed on the housing, and the light transmission window allows light of a scene to enter a light entrance surface of an optical lens of the camera module.

### BRIEF DESCRIPTION OF DRAWINGS

FIG. 1 is a perspective view of an electronic device according to some embodiments of this application;

FIG. 2 is an exploded view of an electronic device in FIG. 1;

FIG. 3 is an internal circuit diagram of the electronic device shown in FIG. 1 and FIG. 2;

FIG. 4 is a perspective view of a camera module in the electronic device shown in FIG. 1 and FIG. 2;

FIG. 5 is an exploded view of the camera module shown in FIG. 4;

FIG. 6 is a schematic diagram of a structure of a support in the camera module shown in FIG. 5;

FIG. 7 is a schematic diagram of a structure of the support shown in FIG. 6 when viewed from bottom to top;

FIG. 8 is a schematic diagram of a structure of a carrier in the camera module shown in

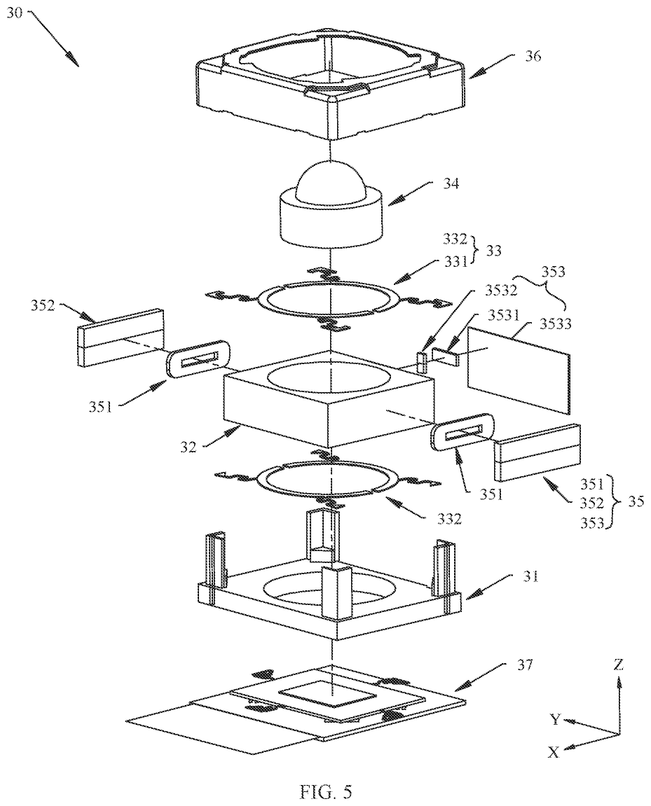

FIG. 5;

FIG. 9 is a schematic diagram of a structure of an optical lens in the camera module shown in FIG. 5;

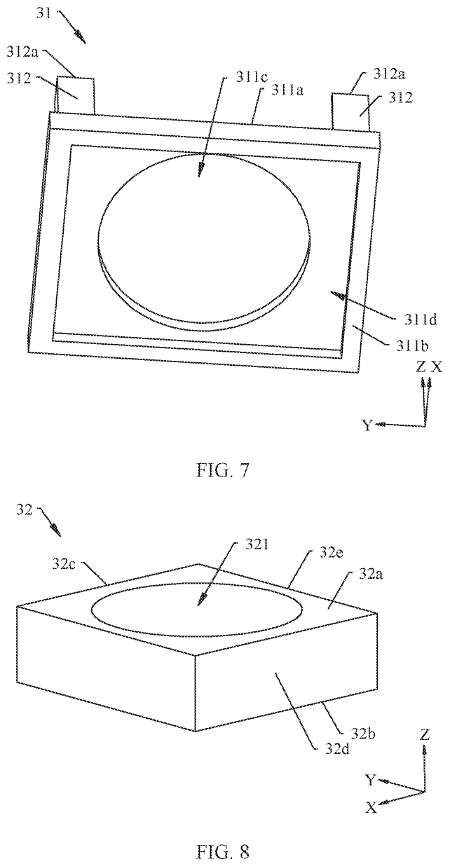

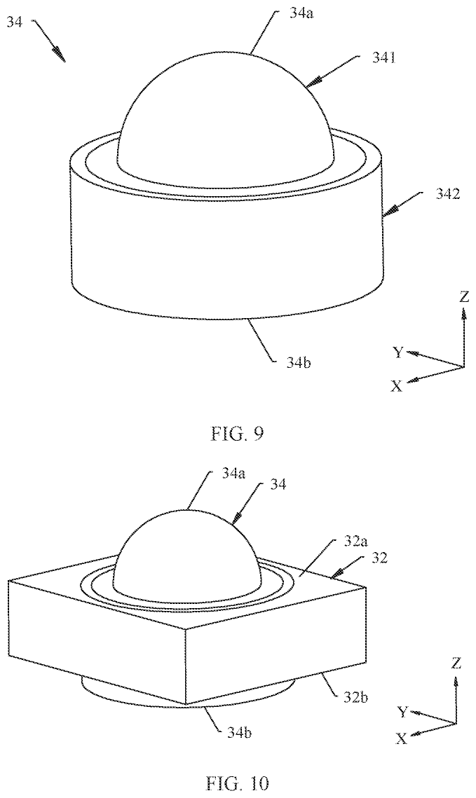

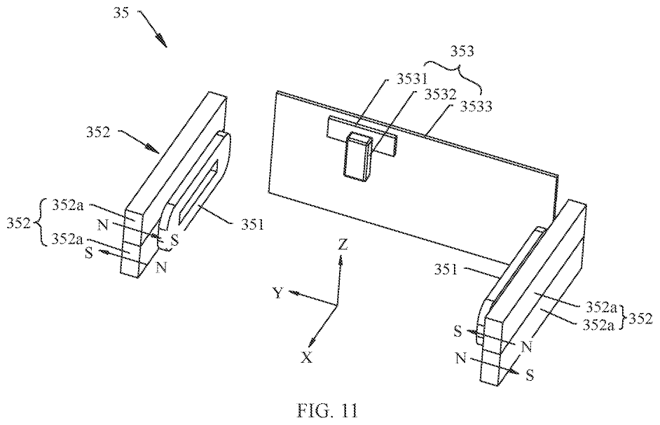

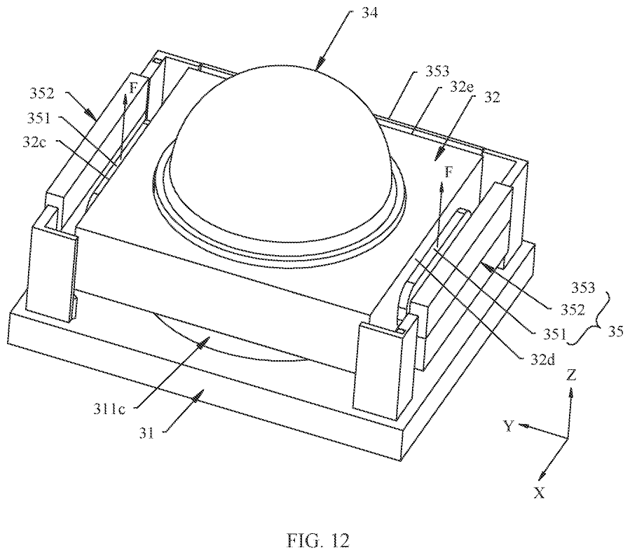

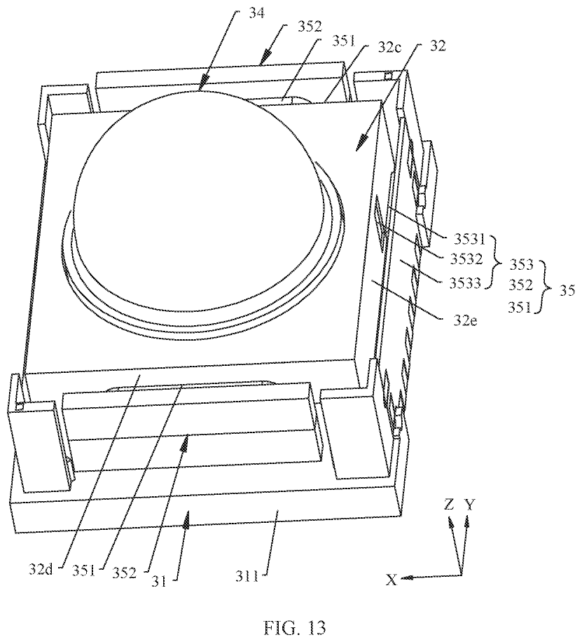

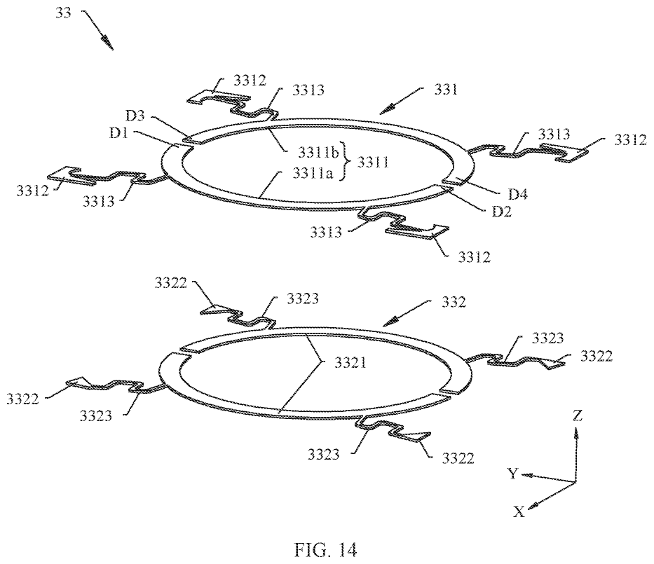

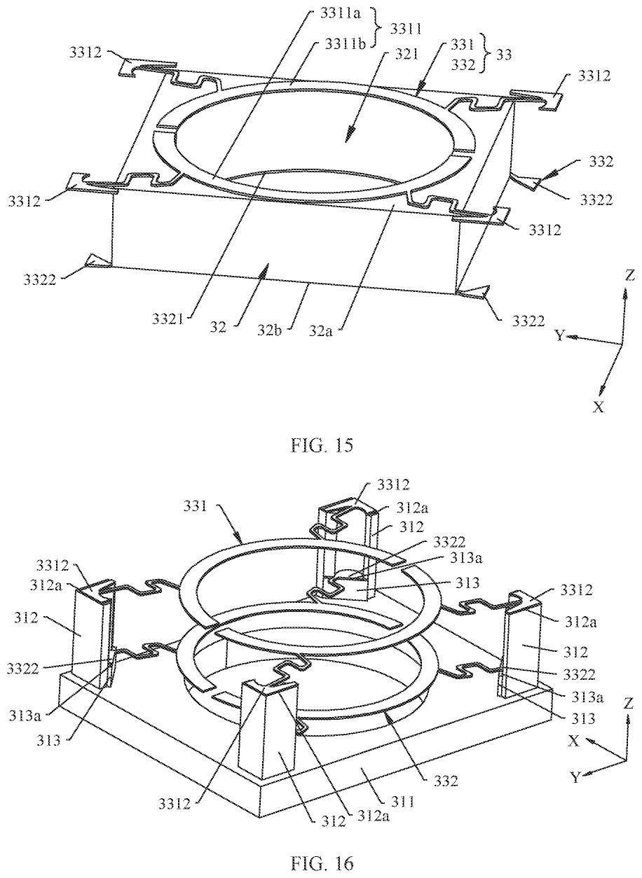

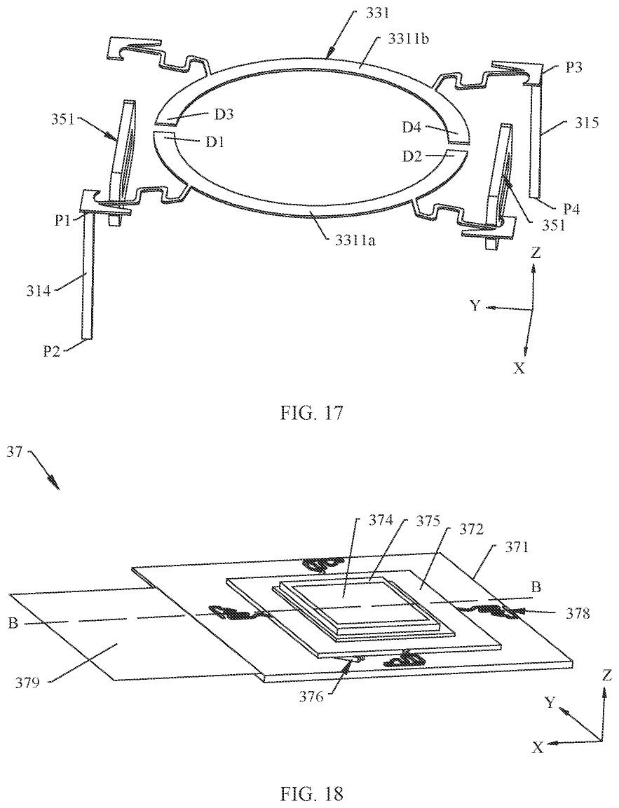

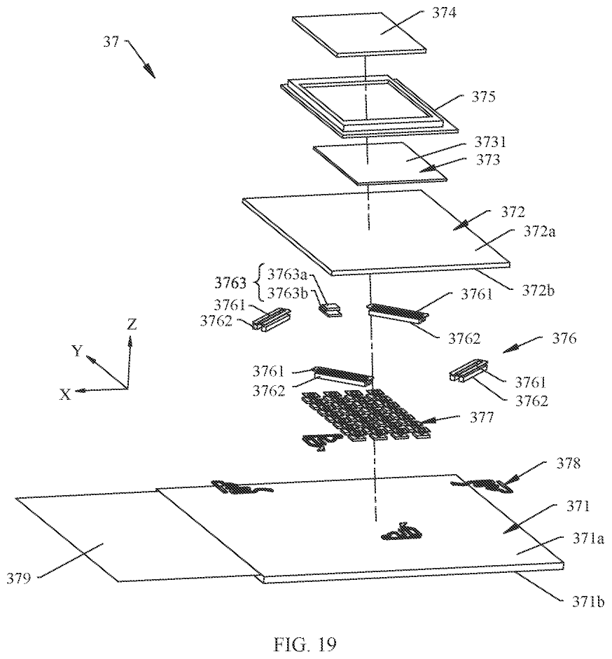

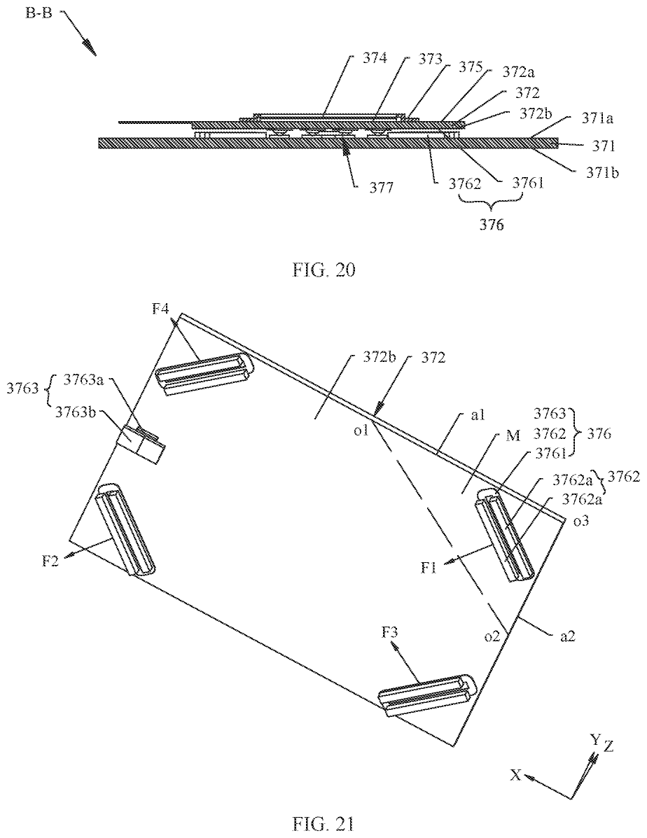

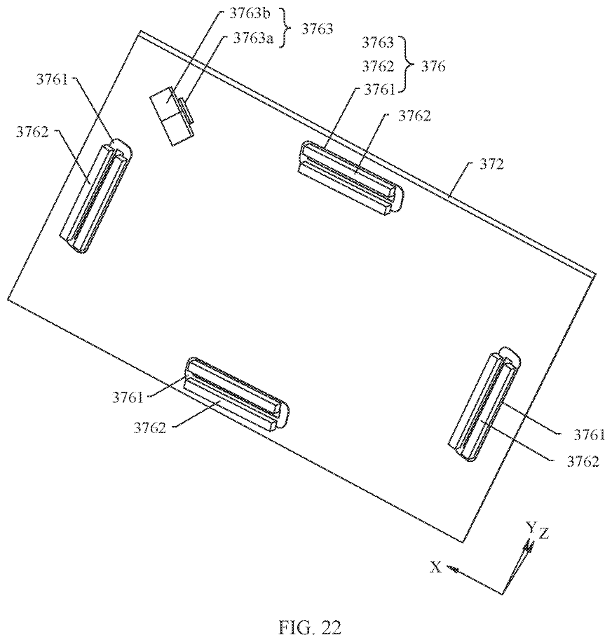

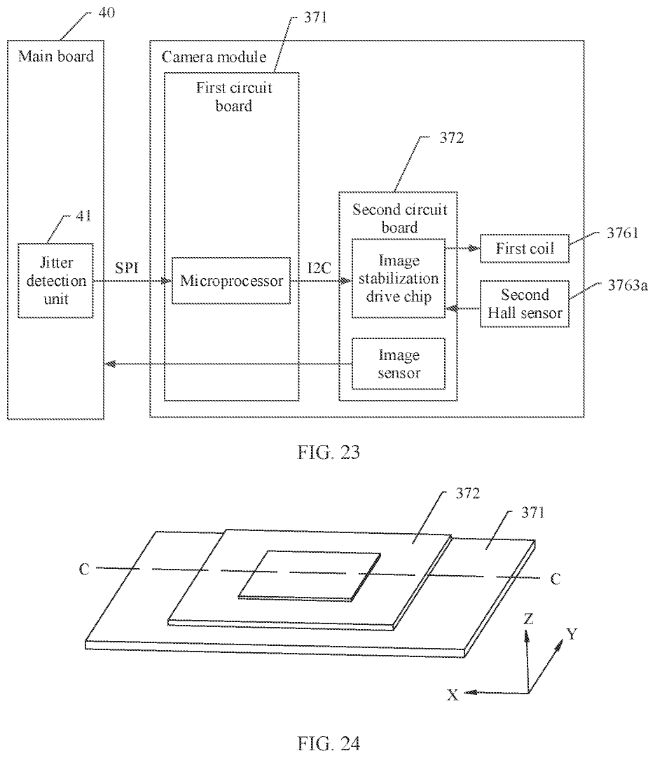

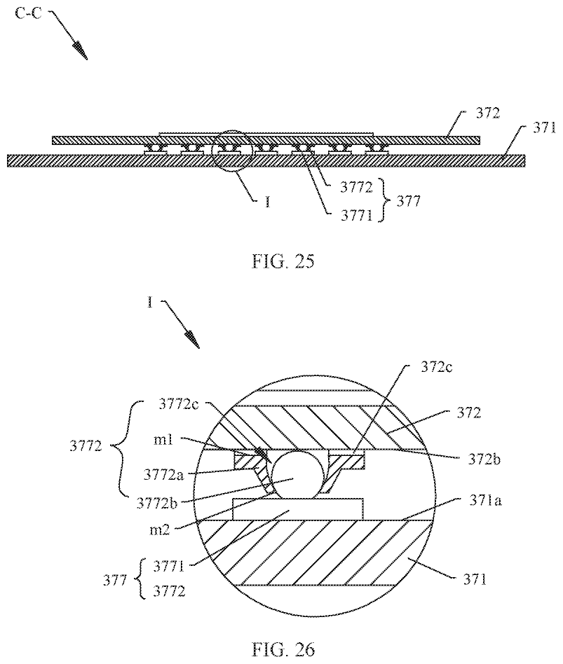

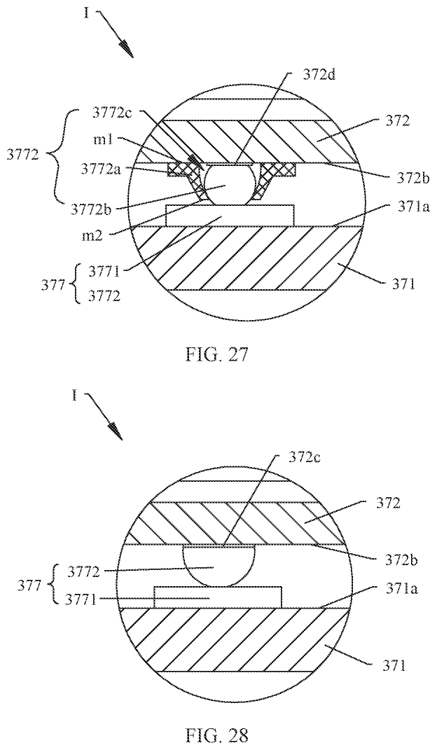

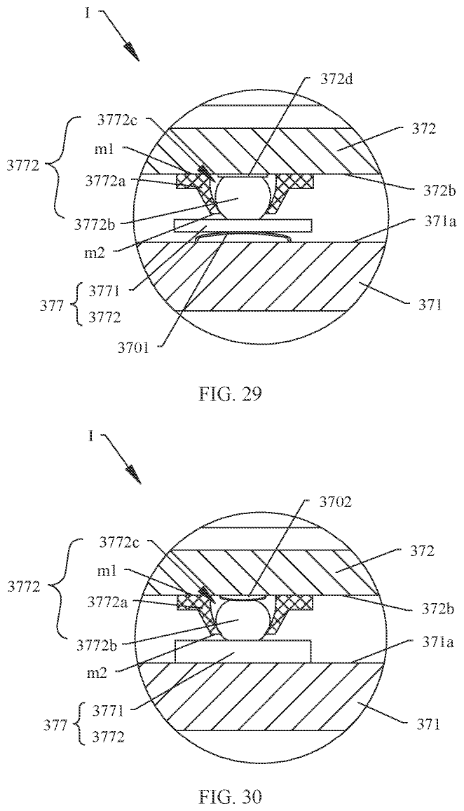

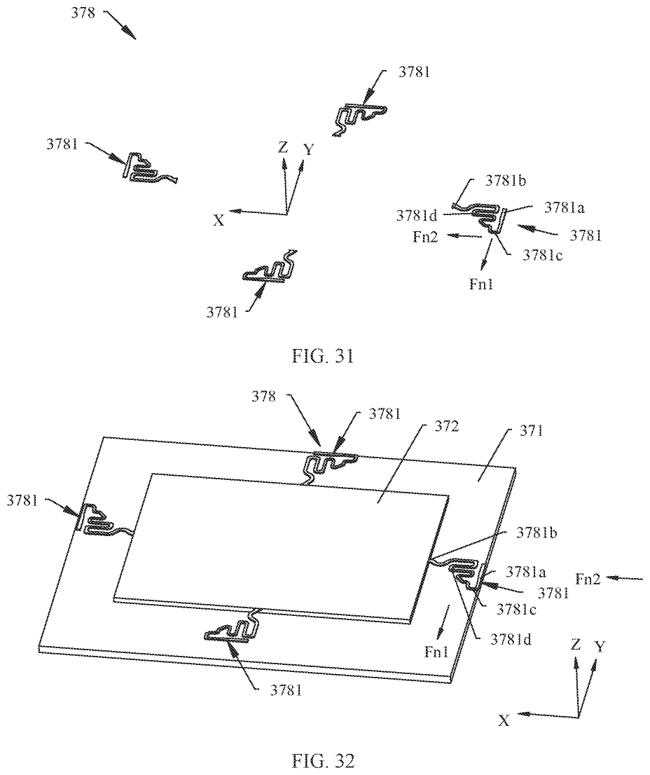

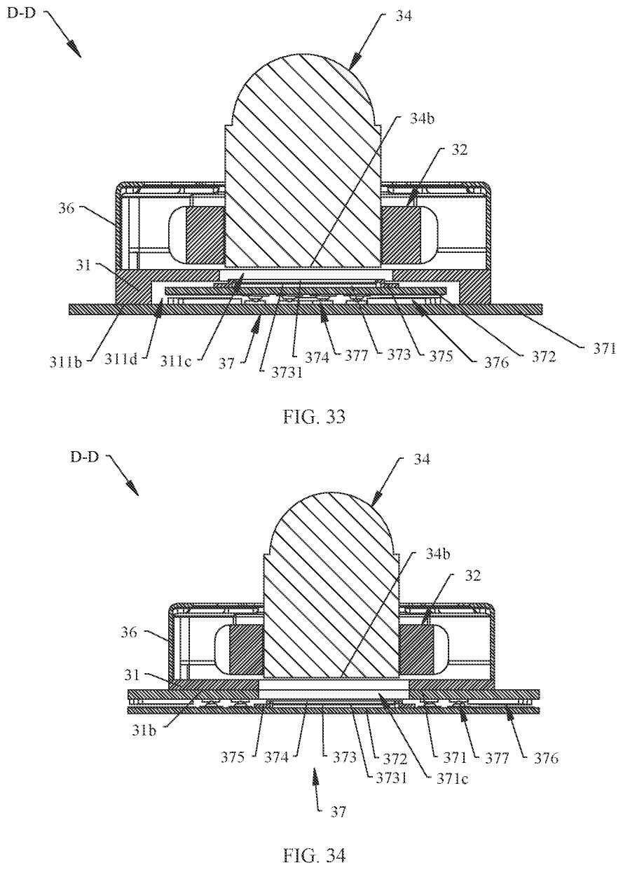

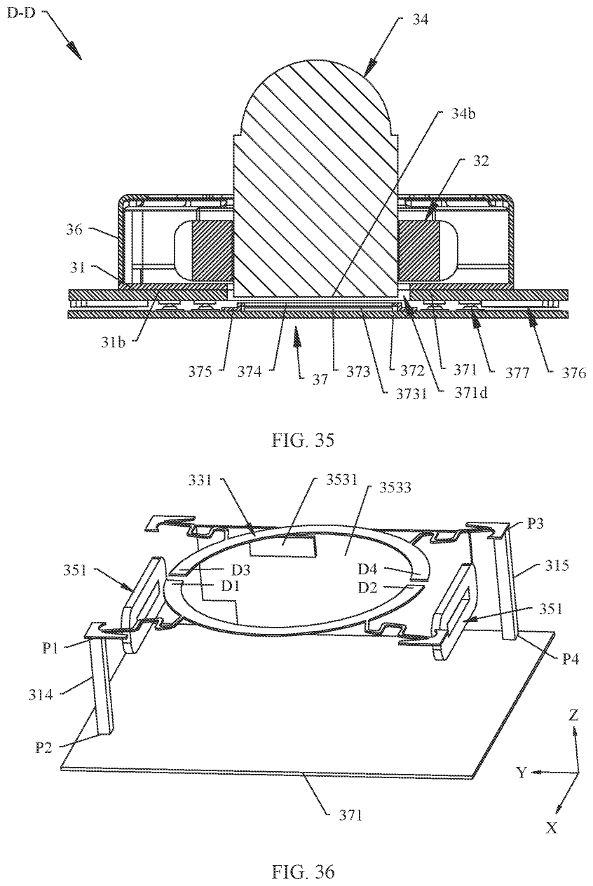

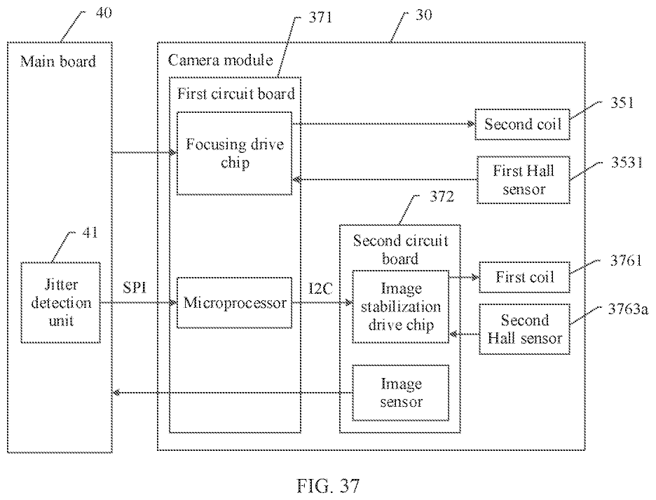

FIG. 10 is an assembly diagram of the optical lens shown in FIG. 9 and the carrier shown in FIG. 8;

FIG. 11 is a schematic diagram of a structure of an automatic focusing apparatus in the camera module shown in FIG. 5;

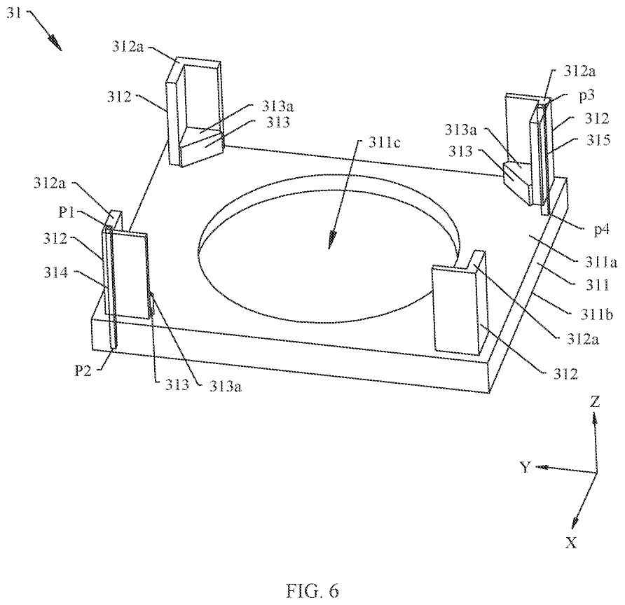

FIG. 12 is an assembly diagram of the automatic focusing apparatus shown in FIG. 11, the optical lens and the carrier shown in FIG. 10 and the support shown in FIG. 6;

FIG. 13 is a schematic diagram of a structure of the assembly structure shown in FIG. 12 at another view angle;

FIG. 14 is a schematic diagram of a structure of an elastic component in the camera module shown in FIG. 5;

FIG. 15 is an assembly diagram of the elastic component shown in FIG. 14 and the carrier in FIG. 12;

FIG. 16 is an assembly diagram of the elastic component shown in FIG. 14 and the support in FIG. 12;

FIG. 17 is a schematic diagram of a structure of a connection between the first elastic member in FIG. 14 and a second coil and a first conductor and a second conductor in the support in FIG. 12;

FIG. 18 is a schematic diagram of a structure of a photosensitive component in the camera module shown in FIG. 4 and FIG. 5;

FIG. 19 is an exploded view of the photosensitive component shown in FIG. 18;

FIG. 20 is a perspective sectional view of the photosensitive component shown in FIG. 18 at a line B-B;

FIG. 21 is an assembly diagram of a second circuit board and an optical image stabilization apparatus in the photosensitive component shown in FIG. 18 to FIG. 20;

FIG. 22 is an assembly diagram of a second circuit board and an optical image stabilization apparatus according to still some other embodiments of this application;

FIG. 23 is a block diagram of an image information transmission circuit and an optical image stabilization control circuit in the photosensitive component shown in FIG. 18 to FIG. 20;

FIG. 24 is an assembly diagram of a first circuit board, a second circuit board, and an electrical connection apparatus in the photosensitive component shown in FIG. 18 to FIG. 20;

FIG. 25 is a schematic diagram of a structure of a cross-section of the assembly diagram shown in FIG. 24 at a line C-C;

FIG. 26 is an enlarged view of a region I in a cross-sectional structure shown in FIG. 25;

FIG. 27 is another enlarged view of a region I in a cross-sectional structure shown in FIG. 25;

FIG. 28 is another enlarged view of a region I in a cross-sectional structure shown in FIG. 25;

FIG. 29 is another enlarged view of a region I in a cross-sectional structure shown in FIG. 25;

FIG. 30 is another enlarged view of a region I in a cross-sectional structure shown in FIG. 25;

FIG. 31 is a schematic diagram of a structure of a limiting apparatus in the photosensitive component shown in FIG. 18 to FIG. 20;

FIG. 32 is an assembly diagram of the limiting apparatus shown in FIG. 31 and a first circuit board and a second circuit board;

FIG. 33 is a schematic diagram of a structure of a cross-section of the camera module shown in FIG. 4 at a line D-D;

FIG. 34 is a schematic diagram of a structure of a cross-section of a camera module according to still some other embodiments of this application;

FIG. 35 is a schematic diagram of a structure of a cross-section of a camera module according to still some other embodiments of this application;

FIG. 36 is an assembly diagram of a first circuit board in a camera module and a first conductor and a second conductor in a support, a carrier, a first elastic member, a first Hall sensor and two second coils in an automatic focusing apparatus according to some embodiments of this application; and

FIG. 37 is an internal circuit block diagram of the camera module shown in FIG. 4.

### DESCRIPTION OF EMBODIMENTS

In embodiments of this application, the terms “first”, “second”, “third”, and “fourth” are used for descriptive purposes only, and cannot be construed as indicating or implying relative importance or implicitly indicating the quantity of technical features indicated. Therefore, the features defined with “first”, “second”, “third”, and “fourth” may explicitly or implicitly include one or more of the features.

In the embodiments of this application, the term “including”, “containing” or any other variant thereof is intended to cover non-exclusive inclusion, so that a process, method, article or apparatus including a series of elements includes not only those elements, but also other elements not explicitly listed, or elements inherent to such a process, method, article or apparatus. Without further limitation, the element defined by the sentence “including a . . . ” does not exclude that other identical elements are also present in the process, method, article or apparatus including the element.

In embodiments of this application, the term “and/or” is only used to describe an association relationship between associated objects, and indicates that three relationships may exist. For example, A and/or B may indicate the following: Only A exists, both A and B exist, and only B exists. In addition, the character “/” in this specification usually indicates an “or” relationship between the associated objects.

This application provides an electronic device, and the electronic device has a camera module, so that a video and a picture can be photographed. In the electronic device provided in this application, two electrically connected circuit boards are disposed in the camera module, and the two circuit boards are stacked. In addition, one circuit board is fixed to a support of the camera module, an image sensor is disposed on the other circuit board, and the other circuit board is driven to move, relative to the circuit board, in a plane in which the other circuit board is located, so as to implement optical image stabilization, thereby improving photographing clarity of the camera module. Because the two circuit boards are stacked, electronic components of the camera module may be distributed on the two circuit boards. In this way, an area of a single circuit board may be reduced, and an occupation space when a circuit board in which an image sensor is located is active may be reduced, so that an occupation area and a volume of the camera module may be reduced, so as to facilitate mounting in an electronic device with a limited space.

Specifically, the electronic device provided in this application may be a portable electronic apparatus or another suitable electronic apparatus. For example, the electronic device may be a mobile phone, a tablet personal computer, a laptop computer, a personal digital assistant (PDA), a camera, a personal computer, a notebook computer, an in-vehicle device, a wearable device, augmented reality (AR) glasses, an AR helmet, virtual reality (VR) glasses, or a VR helmet.

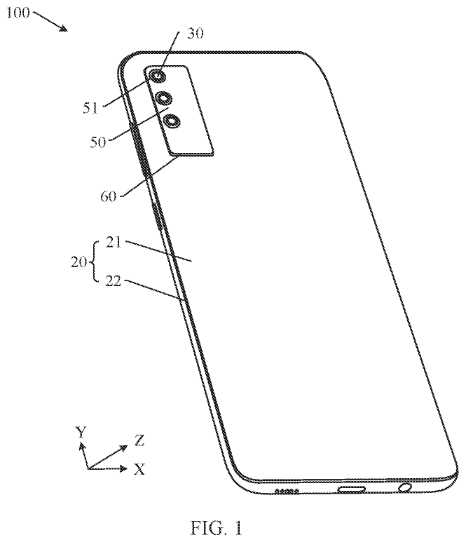

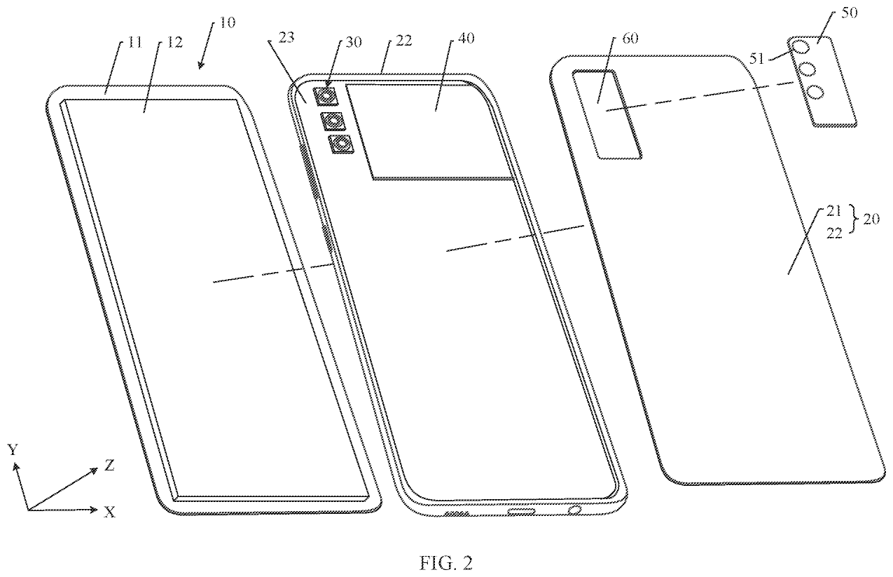

Referring to FIG. 1 and FIG. 2, FIG. 1 is a perspective view of an electronic device 100 according to some embodiments of this application, and FIG. 2 is an exploded view of the electronic device 100 shown in FIG. 1. In this embodiment, the electronic device 100 is a mobile phone. The electronic device 100 includes a screen 10, a rear housing 20, a camera module 30, a main board 40, and a camera decorative cover 50.

It may be understood that FIG. 1 and FIG. 2 show only some components included in the electronic device 100 schematically. Actual shapes, actual sizes, actual locations, and actual constructions of these components are not limited by FIG. 1 and FIG. 2. In some other examples, the electronic device 100 may not include the screen 10 and the camera decorative cover 50.

The screen 10 is configured to display an image, a video, and the like. The screen 10 includes a light-transmitting cover plate 11 and a display 12 (English name: panel, also referred to as a display panel). The light-transmitting cover plate 11 and the display screen 12 are stacked. The light-transmitting cover plate 11 is mainly configured to protect the display screen 12 and prevent dust. A material of the light-transmitting cover plate 11 includes but is not limited to glass. The display screen 12 may use a flexible display screen, or may use a rigid display screen. For example, the display screen 12 may be an organic light-emitting diode (OLED) display screen, an active-matrix organic light-emitting diode or an active-matrix organic light-emitting diode (AMOLED) display screen, a mini organic light-emitting diode display screen, a micro light-emitting diode display screen, a micro organic light-emitting diode display screen, a quantum dot light emitting diode (QLED) display screen, or a liquid crystal display (LCD).

The rear housing 20 is configured to protect an internal electronic component of the electronic device 100. The rear housing 20 includes a back cover 21 and a bezel 22. The back cover 21 is located on a side of the display screen 12 away from the light-transmitting cover plate 11, and is stacked with the light-transmitting cover plate 11 and the display screen 12. The bezel 22 is located between the back cover 21 and the light-transmitting cover plate 11, and the bezel 22 is fixed to the back cover 21. For example, the bezel 22 may be fixed to the back cover 21 by using adhesive. The bezel 22 and the back cover 21 may alternatively be an integrated structure, that is, the bezel 22 and the back cover 21 are an integral structure. The light-transmitting cover plate 11 is bonded to the bezel 22 by using adhesive. The light-transmitting cover plate 11, the back cover 21, and the bezel 22 form an internal accommodation space of the electronic device 100. The internal accommodation space accommodates the display screen 12.

To facilitate the following description, an XYZ coordinate system is established, and a stacking direction (that is, a thickness direction of the electronic device 100) of the light-transmitting cover plate 11, the display screen 12, and the back cover 21 in the electronic device 100 is defined as a Z-axis direction. A plane in which the light-transmitting cover plate 11, the display screen 12, or the back cover 21 is located is an XY plane. It may be understood that, a coordinate system of the electronic device 100 may be flexibly set according to actual needs.

The camera module 30 is configured to photograph a photo/a video. The camera module 30 is a type of camera module that has an optical image stabilization (OIS) function. The camera module 30 is fixed to an internal accommodation cavity of the electronic device 100. For example, the camera module 30 may be fixed to a surface of the display screen 12 near the back cover 21 in a manner such as threaded connection, clamping, or welding. In another embodiment, referring to FIG. 2, the electronic device 100 further includes a middle plate 23. The middle plate 23 is fixed to a circumference of an inner surface of the bezel 22. For example, the middle plate 23 may be welded to the bezel 22. The middle plate 23 and the bezel 22 may alternatively be an integrated structure. The middle plate 23 is used as a “skeleton” of a structure of the electronic device 100, and the camera module 30 may be fixed on the middle plate 23 through screwing, clamping, welding, or the like.

The camera module 30 may be used as a rear camera module, or may be used as a front camera module.

For example, referring to FIG. 2, the camera module 30 is fixed to a surface of the middle plate 23 close to the back cover 21, and a light entrance surface of the camera module 30 faces the back cover 21. A mounting port 60 is disposed on the back cover 21, and the camera decorative cover 50 covers and is fixed to the mounting port 60. The camera decorative cover 50 and the back cover 20 form a housing of the electronic device 100. The camera decorative cover 50 is configured to protect the camera module 30. In some embodiments, the camera decorative cover 50 protrudes to a side of the back cover 21 away from the light-transmitting cover plate 11. In this way, the camera decorative cover 50 can increase a mounting space of the camera module 30 in the Z-axis direction in the electronic device 100. In some other embodiments, the camera decorative cover 50 may alternatively be flush with the back cover 21 or recessed inward into the internal accommodation space of the electronic device 100. A light transmission window 51 is disposed on the camera decorative cover 50. The light transmission window 51 allows light of scene to be incident on the light entrance surface of the camera module 30. In this embodiment, the camera module 30 serves as a rear camera module of the electronic device 100. For example, the camera module 30 may be used as a rear main camera module. In another example, the camera module 30 may alternatively be used as a rear wide-angle camera module or a long-focus camera module.

In another embodiment, the camera module 30 is fixed to a surface of the middle plate 23 near the light-transmitting cover plate 11. The light entrance surface of the camera module 30 faces the light-transmitting cover plate 11. An optical path avoidance hole is disposed on the display screen 12. The optical path avoidance hole allows light of a scene to pass through the light-transmitting cover plate 11 and then be incident on the light entrance surface of the camera module 30. In this way, the camera module 30 serves as a front camera module of the electronic device 100.

The main board 40 is disposed in the internal accommodation cavity of the electronic device 100. In some embodiments, referring to FIG. 2, the main board 40 is fixed to the surface of the middle board 23 near the light-transmitting cover plate 11. The main board 40 may be electrically connected to the display screen 10 and the camera module 30, so as to store and process image information obtained by the camera module 30, and can send the image information to the screen 10 for display.

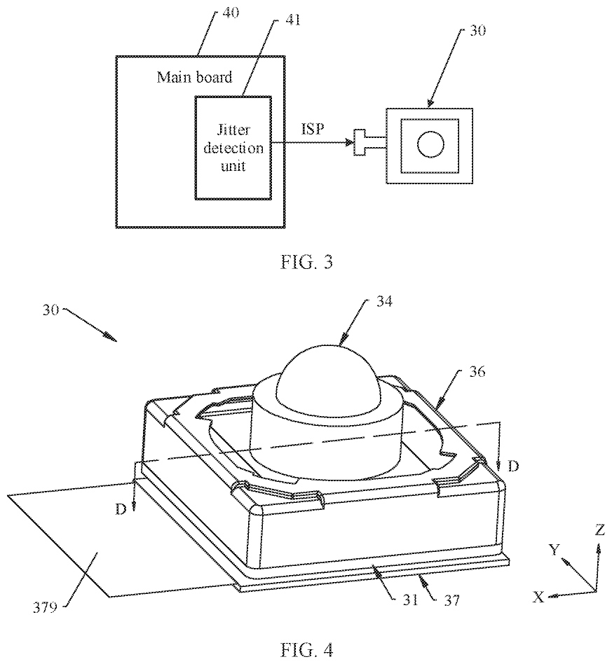

FIG. 3 is an internal circuit diagram of the electronic device 100 shown in FIG. 1 and FIG. 2. The electronic device 100 further includes a jitter detection unit 41. The jitter detection unit 41 is configured to detect jitter information of the electronic device 100. In some embodiments, the jitter detection unit 41 is a gyro. The jitter detection unit 41 is electrically connected to the camera module 30, so as to transmit the detected jitter information to the camera module 30. In some embodiments, the jitter detection unit 41 transmits the jitter information to the camera module 30 by using a serial peripheral interface (SPI) data line. Based on this, the camera module 30 implements OIS movement according to the jitter information.

In some embodiments, the jitter detection unit 41 may be disposed on the main board 4. In some other embodiments, the jitter detection unit 41 may alternatively be disposed on another circuit board in the electronic device, for example, is disposed on a circuit board on which a universal serial bus (USB) component is located. In this application, that the jitter detection unit 41 is disposed on the main board 4 is only used as an example for description. This should not be considered to constitute a special limitation on this application.

Referring to FIG. 4 and FIG. 5, FIG. 4 is a perspective view of the camera module 30 in the electronic device 100 shown in FIG. 1 and FIG. 2, and FIG. 5 is an exploded view of the camera module 30 shown in FIG. 4. In this embodiment, the camera module 30 includes a support 31, a carrier 32, an elastic component 33, an optical lens 34, an automatic focusing (AF) apparatus 35, a housing 36, and a photosensitive component 37.

It may be understood that FIG. 4 and FIG. 5 show only some components included in the camera module 30 schematically. Actual shapes, actual sizes, actual locations, and actual constructions of these components are not limited by FIG. 4 and FIG. 5. In addition, a coordinate system in FIG. 4 and FIG. 5 and a coordinate system in FIG. 1 and FIG. 2 are represented as a same coordinate system. That is, a location relationship of each component in the camera module 30 in FIG. 4 and FIG. 5 in the coordinate system shown in FIG. 4 and FIG. 5 is the same as a location relationship of each component in the camera module 30 in the coordinate system shown in FIG. 1 and FIG. 2 when the camera module 30 is applied to the electronic device 100 in FIG. 1 and FIG. 2. A coordinate system in the accompanying drawings of the components in the camera module 30 described below and the coordinate system in the camera module 30 shown in FIG. 4 and FIG. 5 are also represented as a same coordinate system. The “same coordinate system” and the foregoing same coordinate system should be considered to be the same. Details are not described later.

It should be noted that, the “top” used by each component in the camera module 30 described in the following refers to a part of the described component close to the light transmission window 51 along the optical path when the camera module 30 is applied to the electronic device 100 shown in FIG. 1 and FIG. 2. The “bottom” refers to a part of the described component away from the light transmission window 51 along the optical path when the camera module 30 is applied to the electronic device 100 shown in FIG. 1 and FIG. 2. This does not indicate or imply that the referred apparatus or component must have a specific direction and must be constructed and operated in a specific direction. Therefore, this is not understood as a limitation on this application. In addition, a shape of each component in the camera module 30 being “rectangle” or “square” as described below indicates an approximate shape, two adjacent sides are approximately vertical, and a round angle may be or may not be disposed between two adjacent sides. In addition, location relationship qualifiers such as “parallel”, “vertical”, and “consistent” that are used for the components in the camera module 30 as described below indicate an approximate relationship in which an error is allowed.

The support 31 serves as a structure “skeleton” of the camera module 30, and is configured to support and fix another component in the camera module 30. Generally, when the camera module 30 is mounted in the electronic device 100, the support 31 is fixed to the structure “skeleton” of the electronic device 100. A material of the support 31 includes but is not limited to metal and plastic. In some embodiments, the material of the support 31 is plastic. For example, the material of the support 31 is a liquid crystal polymer (LCP).

FIG. 6 is a schematic diagram of a structure of the support 31 in the camera module 30 shown in FIG. 5. The support 31 includes a substrate part 311, a first support part 312, and a second support part 313.

The substrate part 311 includes back-to-back top surface 311a and bottom surface 311b. The substrate part 311 is provided with an avoidance hole 311c that runs through the top surface 311a of the substrate part 311 and the bottom surface 311b of the substrate part 311.

Both the first support part 312 and the second support part 313 are fixed to the top surface 311a of the substrate part 311, and both the first support part 312 and the second support part 313 extend from the top surface 311a of the substrate part 311 to a direction away from the bottom surface 311b of the substrate part 311. A cross-section of the first support part 312 is L-shaped, and an included angle region is formed between two side parts of the first support part 312, where the included angle region is located on a side of the first support part 312 close to a central axis of the avoidance hole 311c. The second support part 313 is located in the included angle region of the first support part 312, and a height of the second support part 313 is less than a height of the first support part 312. A surface of the first support part 312 away from the substrate part 311 is a top surface 312a of the first support part 312, and a surface of the second support part 313 away from the substrate part 311 is a top surface 313a of the second support part 313.

In some embodiments, quantities of the first support parts 312 and the second support parts 313 are both four, the four first support parts 312 are uniformly disposed around a circumferential direction of the avoidance hole 311c, and the four second support parts 313 are disposed in a one-to-one correspondence manner in included angle regions of the four first support parts 312. In FIG. 6, one second support part 313 is shielded by a corresponding first support part 312. Therefore, only three second support parts 313 are shown. In some other embodiments, the quantities of the first support parts 312 and the second support parts 313 may alternatively be 6, 8, or 12.

A first conductor 314 and a second conductor 315 are embedded in the support 31. The first conductor 314 has a first end p1 and a second end p2. The second conductor 315 has a third end p3 and a fourth end p4. The first end p1 and the third end p 3 are respectively located on top surfaces 312a of two first support parts 312 disposed diagonally. The second end p2 and the fourth end p4 are located on the bottom surface 311b of the substrate part 311. In some other embodiments, the first conductor 314 and the second conductor 315 may alternatively be disposed on the surface of the support 31.

FIG. 7 is a schematic diagram of a structure of the support 31 shown in FIG. 6 when viewed from bottom to top. An accommodating groove 311d is disposed on the bottom surface 311b of the substrate part 311.

FIG. 8 is a schematic diagram of a structure of the carrier 32 in the camera module 30 shown in FIG. 5. The carrier 32 is generally in a rectangular shape. In some other embodiments, the carrier 32 may alternatively be square, cylindrical, or the like. The carrier 32 has back-to-back top face 32a and bottom face 32b. A lens mounting hole 321 that runs through the top surface 32a and the bottom surface 32b is disposed on the carrier 32.

The carrier 32 further has a first outer side surface 32c, a second outer side surface 32d, and a third outer side surface 32e that are connected between the top surface 32a and the bottom surface 32b, where the first outer side surface 32c is back to back with the second outer side surface 32d, and the third outer side surface 32e is located between the first outer side surface 32c and the second outer side surface 32d.

FIG. 9 is a schematic diagram of a structure of an optical lens 34 in the camera module 30 shown in FIG. 5. The optical lens 34 is configured to image a photographed object. For example, the optical lens 34 may be an upright lens, and an optical axis of the upright lens extends in the Z-axis direction. The optical lens 34 may alternatively be a periscope lens, and an optical axis of the periscope lens is parallel to the XY plane. In this embodiment of this application, that the optical lens 34 is an upright lens is only used as an example for description. This should not be considered to constitute a special limitation on this application.

The optical lens 34 includes a lens barrel 341 and an optical lens group 342. The lens barrel 341 is configured to fix and protect the optical lens group 342. The lens barrel 341 is of a cylindrical structure. That is, the lens barrel 341 is opened at two ends in an optical axis direction. The optical lens group 342 is mounted in the lens barrel 341. The optical lens group 342 includes at least one optical lens. When the optical lens group 342 includes a plurality of optical lenses, the plurality of optical lenses are stacked in the optical axis direction. By designing the structure composition of the optical lens group 342 and the shape and size of each optical lens, an optical lens with different features such as standard, wide angle, and long focal length can be obtained.

The optical lens 34 is configured to be mounted in the lens mounting hole 321 of the carrier 32 in FIG. 8. On this basis, optionally, the optical lens 34 may not be disposed with the lens barrel 341, and the optical lens group 342 of the optical lens 34 is mounted and fixed in the lens mounting hole 321 of the carrier 32. Therefore, the optical lens group 342 is fixed and protected by using the carrier 32, so as to integrate the carrier 32 and the optical lens 34, thereby reducing a volume of the camera module 30.

Still referring to FIG. 9, the optical lens 34 has back-to-back light entrance surface 34a and light emitting surface 34b. Light of a scene is incident into the optical lens 34 from the light entrance surface 34a, and is emitted from the light emitting surface 34b.

FIG. 10 is an assembly diagram of the optical lens 34 shown in FIG. 9 and the carrier 32 shown in FIG. 8. The optical lens 34 is mounted in the lens mounting hole 321 of the carrier 32, and the optical axis direction of the optical lens 34 is the same as an axial direction of the lens mounting hole 321. The light entrance surface 34a of the optical lens 34 is the same as an orientation of the top surface 32a of the carrier 32, and the light emitting surface 34b of the optical lens 34 is the same as an orientation of the bottom surface 32b of the carrier 32.

FIG. 11 is a schematic diagram of a structure of an automatic focusing apparatus 35 in the camera module 30 shown in FIG. 5. The automatic focusing apparatus 35 includes a second coil 351 and a second magnet 352.

FIG. 12 is an assembly diagram of the automatic focusing apparatus 35 shown in FIG. 11, the optical lens 34 and the carrier 32 shown in FIG. 10, and the support 31 shown in FIG. 6, and the second coil 351 is mounted on an outer side surface of the carrier 32. In some embodiments, there are two second coils 351, and the two second coils 351 are respectively mounted on a first outer side surface 32c and a second outer side surface 32d of the carrier 32. The second magnet 352 is mounted on the support 31. In some embodiments, there are two second magnets 352. The two second magnets 352 are mounted on the substrate part 311 of the support 31, and the two second magnets 352 are respectively opposite to the two second coils 351. Under an action of a magnetic field of the second magnet 352, when the second coil 351 is energized, a Lorenz force F parallel to the optical axis of the optical lens 34 is generated. The Lorenz force F may drive the carrier 32 and drive the optical lens 34 to move in the optical axis direction of the optical lens 34, so as to implement automatic focusing. Compared with the magnet, a weight of the coil is usually relatively small, which helps reduce complexity of the automatic focusing apparatus 35, and therefore helps reduce a volume and costs of the automatic focusing apparatus 35.

In an automatic focusing process, the avoidance hole 311c of the substrate part 311 allows the optical lens 34 to extend into the substrate part 311, so as to increase a focusing stroke, or reduce a height of the camera module 30 on the Z-axis while ensuring the focusing stroke.

Specifically, referring back to FIG. 11, each second magnet 352 includes two magnet units 352a, the two magnet units 352a are respectively opposite to two opposite sides of the second coil 351, and magnetic charging directions (that is, a direction from an N-pole to an S-pole) of the two magnet units 352a are opposite, so that the two opposite sides of the second coil 351 are subject to Lorentz forces in a same direction.

In some other embodiments, there are four second coils 351 and four second magnets 352. The four second coils 351 are separately located around the carrier 32. The four second magnets 352 are respectively opposite to the four second coils 351. In this way, drive strength may be increased through cooperation among the four second magnets 352 and the four second coils 351.

In some other embodiments, mounting locations of the second coils 351 and the second magnets 352 may also be interchangeable. That is, the second magnet 352 is mounted on the outer side surface of the carrier 32, and the second coil 351 is mounted on the substrate part 311 of the support 31.

It should be noted that the automatic focusing apparatus 35 is configured to drive the carrier 32 and drive the optical lens 34 to move in the optical axis direction of the optical lens 34, so as to implement automatic focusing. In this case, the automatic focusing apparatus 35 may be in another structural form, which is not specifically limited herein.

FIG. 13 is a schematic diagram of a structure of the assembly structure shown in FIG. 12 at another view angle. In addition to the second coil 351 and the second magnet 352, the automatic focusing apparatus 35 further includes a first location detection apparatus 353, where the first location detection apparatus 353 is configured to detect a location of the carrier 32 relative to the support 31, so as to implement automatic focusing closed-loop control. In some embodiments, the first location detection apparatus 353 includes a first Hall sensor 3531 and a third magnet 3532. The first Hall sensor 3531 is relatively fixed to the support 31. The third magnet 3532 is fixed to the carrier 32. For example, the third magnet 3532 is embedded in a third outer side surface 32e of the carrier 32. In some other embodiments, the third magnet 3532 may also be fixed on the third outer side surface 32e of the carrier 32. The first Hall sensor 3531 cooperates with the third magnet 3532 to obtain the location of the carrier 32 relative to the support 31.

On the basis of the foregoing embodiment, referring back to FIG. 11, the first location detection apparatus 353 further includes an electrical connector 3533, and the electrical connector 3533 is a printed circuit board (PCB). Still referring to FIG. 13, the electrical connector 3533 is fixed to the substrate part 311 of the support 31, and the first Hall sensor 3531 is disposed on the electrical connector 3533. The first Hall sensor 3531 leads a detected focusing distance signal to the bottom of the support 31 by using the electrical connector 3533, and implements indirect fixing to the support 31 by using the electrical connector 3533. In some other embodiments, the electrical connector 3533 may alternatively be a flexible printed circuit (FPC) board, a wire, or an enamelled wire.

In some other embodiments, the camera module 30 may form an open-loop auto-focusing structure without disposing the first location detection apparatus 353 to.

In some other embodiments, setting locations of the first Hall sensor 3531 and the third magnet 3532 may be interchangeable. That is, the first Hall sensor 3531 is fixed to the third outer side surface 32e of the carrier 32, and the third magnet 3532 is relatively fixed to the support 31.

FIG. 14 is a schematic diagram of a structure of an elastic component 33 in the camera module 30 shown in FIG. 5. The elastic component 33 includes a first elastic structure 331 and a second elastic structure 332. In some embodiments, both the first elastic structure 331 and the second elastic structure 332 are conductive springs. In a space-allowed scenario, the first elastic structure 331 and the second elastic structure 332 may alternatively be helical springs. In a scenario in which a required elastic force is relatively small, the first elastic structure 331 and the second elastic structure 332 may alternatively be elastic rubber strips.

The first elastic structure 331 includes a first fixing part 3311, a second fixing part 3312, and a first spring arm part 3313.

The first fixing part 3311 includes a first fixing unit 3311a and a second fixing unit 3311b. The first fixing unit 3311a and the second fixing unit 3311b are generally strip-shaped extending along a semi-circular arc, the first fixing unit 3311a and the second fixing unit 3311b are concatenated into a circular ring, and there is a gap between the first fixing unit 3311a and the second fixing unit 3311b. The first fixing unit 3311a has a first end D1 and a second end D2. The second fixing unit 3311b has a third end D3 and a fourth end D4.

The second fixing part 3312 is located on the outside of the first fixing part 3311. The first spring arm part 3313 is connected between the first fixing part 3311 and the second fixing part 3312, and the first spring arm part 3312 has an elastic stretching and bending deformation capability, so as to allow the first fixing part 3311 to move relative to the second fixing part 3312.

In some embodiments, a quantity of the second fixing parts 3312 and a quantity of the first spring arm parts 3313 are both four, and the four second fixing parts 3312 and the four first spring arm parts 3313 are evenly disposed around an outer circumference of the first fixing part 3311. In the four first spring arm parts 3313, two first spring arm parts 3313 are connected between the first fixing unit 3311a and two second fixing units 3312, and the other two first spring arm parts 3313 are connected between the second fixing unit 3311b and the other two second fixing units 3312.

The second elastic structure 332 includes a third fixing part 3321, a fourth fixing part 3322, and a second spring arm part 3323. The second spring arm part 3323 is connected between the third fixing part 3321 and the fourth fixing part 3322, and the second spring arm part 3323 has an elastic stretching and bending deformation capability, so that the third fixing part 3321 is allowed to move relative to the fourth fixing part 3322. Specifically, a structure of the second elastic structure 332 is similar to a structure of the first elastic structure 331, and details are not described herein again.

FIG. 15 is an assembly diagram of the elastic component 33 shown in FIG. 14 and the carrier 32 in FIG. 12, and FIG. 16 is an assembly diagram of the elastic component 33 shown in FIG. 14 and the support 31 in FIG. 12.

In the elastic component 33, the first fixing part 3311 of the first elastic structure 331 is fixed to the top surface 32a of the carrier 32, and the second fixing part 3312 of the first elastic structure 331 is fixed to the top surface 312a of the first support part 312. The third fixing part 3321 of the second elastic structure 332 is fixed to the bottom surface 32b of the carrier 32, and the fourth fixing part 3322 of the second elastic structure 332 is fixed to the top surface 313a of the second support part 313.

In this way, the carrier 32 is elastically supported on the support 31 by using the elastic component 33, so that the carrier 32 can be reset after one automatic focusing operation, which does not affect a next focusing operation.

On this basis, FIG. 17 is a schematic diagram of a structure of a connection between the first elastic structure 331 in FIG. 14 and the second coil 351 and the first conductor 314 and the second conductor 315 in the support 31 in FIG. 12. In the first elastic structure 331, the first end D1 of the first fixing unit 3311a and the third end D3 of the second fixing unit 3311b are respectively electrically connected to a positive electrode and a negative electrode of one second coil 351. The second end D2 of the first fixing unit 3311a and the fourth end D4 of the second fixing unit 3311b are respectively electrically connected to a positive electrode and a negative electrode of another second coil 351. A second fixing part 3312 connected to the first fixing unit 3311a is electrically connected to the first end p1 of the first conductor 314. A second fixing part 3312 connected to the second fixing unit 3311b is electrically connected to the third end p3 of the second conductor 315.

In this way, electrodes of two second coils 351 in the automatic focusing apparatus 35 are led out to the support 31 by using the first elastic structure 331, and the electrodes of the two second coils 351 are further led out to the bottom of the support 31 by using the first conductor 314 and the second conductor 315. Two second coils 351 are disposed in parallel.

It should be noted that the elastic component 33 is configured to elastically support the carrier 32 on the support 31. On the premise of achieving this objective, the elastic component 33 may have another structural form. In addition, in some other embodiments, electrodes of two second coils 351 may be led out by using the second elastic structure 332 in the elastic component 33. For specific implementation details, refer to the foregoing embodiments. Details are not described herein again.

Referring back to FIG. 4 and FIG. 5, the camera module 30 further includes a housing 36, where the housing 36 is fixed to the support 31, and a part of the support 31, the carrier 32, the elastic component 33, a part of the optical lens 34, and the automatic focusing apparatus 35 are disposed therein, so as to perform waterproof and dust protection on these components.

A material of the housing 36 includes but is not limited to metal and plastic. In some embodiments, the material of the housing 36 may be selected as metal. Specifically, the metal includes but is not limited to an aluminum alloy, a magnesium aluminum alloy, and the like. Structure strength of the metal is relatively good, so that a wall thickness of the housing 36 can be reduced while structural strength of the housing 36 is ensured, and heat dissipation performance of the metal is relatively good, which facilitates heat dissipation of an internal electronic component. In some other embodiments, the camera module 30 may not be disposed with the housing 36.

According to the foregoing description, the camera module 30 provided in this application is a type of camera module that has an automatic focusing function. In some other embodiments, the camera module 30 may alternatively not have an automatic focusing function. In this embodiment, the optical lens 34 may be directly fixed to the support 31. Based on the camera module 30 that has an automatic focusing function or that does not have an automatic focusing function, the following mainly describes a photosensitive component 37 of the camera module 30.

Referring to FIG. 18 to FIG. 20, FIG. 18 is a schematic diagram of a structure of a photosensitive component 37 in the camera module 30 shown in FIG. 4 and FIG. 5, FIG. 19 is an exploded view of the photosensitive component 37 shown in FIG. 18, and FIG. 20 is a schematic diagram of a structure of a cross-section of the photosensitive component 37 shown in FIG. 18 at a line B-B. It should be noted that, “at the line B-B” refers to a plane in which the line B-B and arrows at both ends of the line B-B are located. Description of similar drawings later should be understood similarly, and details are not described again.

The photosensitive component 37 includes a first circuit board 371, a second circuit board 372, an image sensor 373, a filter 374, a bracket 375, an optical image stabilization apparatus 376, an electrical connection apparatus 377, and a limiting apparatus 378.

A plane in which the first circuit board 371 is located is parallel to the XY plane, and the first circuit board 371 is configured to be fixed to the support 31 shown in FIG. 6. The first circuit board 371 has back-to-back top surface 371a and bottom surface 371b.

The second circuit board 372 is disposed on a side of the top surface 371a of the first circuit board 371 away from the bottom surface 371b of the first circuit board 371, and the second circuit board 372 is stacked with the first circuit board 371. That is, the plane in which the first circuit board 371 is located is also parallel to the XY plane, and an orthographic projection of the second circuit board 372 on the first circuit board 371 overlaps the first circuit board 371. The second circuit board 372 has back-to-back top surface 372a and bottom surface 372b. The bottom surface 372b of the second circuit board 372 is opposite to the top surface 371a of the first circuit board 371.

An area of the second circuit board 372 is less than an area of the first circuit board 371, and an orthographic projection of the second circuit board 372 on the first circuit board 371 is located in the first circuit board 371. In some other embodiments, the area of the second circuit board 372 may alternatively be equal to or greater than the area of the first circuit board 371.

The first circuit board 371 and the second circuit board 372 are hard circuit boards. In some other embodiments, the first circuit board 371 and the second circuit board 372 may be flexible circuit boards, or may be soft and hard combination circuit boards. The first circuit board 371 and the second circuit board 372 may use an FR-4 dielectric board, may use a Rogers (Rogers) dielectric board, may use a mixed dielectric board of Rogers and FR-4, or the like. When the first circuit board 371 and the second circuit board 372 are flexible circuit boards or soft and hard combination circuit boards, two hard reinforcing boards may be disposed to separately increase strength of the first circuit board 371 and the second circuit board 372.

The image sensor 373 is configured to: collect an imaging beam obtained by imaging of the optical lens, and convert image information carried in the imaging beam into an electrical signal. The image sensor 373 may also be referred to as a photosensitive chip, or may be referred to as a photosensitive element. The image sensor 373 is disposed on the top surface 372a of the second circuit board 372, and a surface of the image sensor 373 away from the first circuit board 371 is a light sensing surface 3731.

The filter 374 is located on a side facing the light sensing surface 3731. The filter 374 is fixed to the second circuit board 372 by using the bracket 375. Specifically, the bracket 375 may be fixed to the second circuit board 372 in a manner such as bonding, clamping, and threaded connection, and the optical filter 374 may be fixed to the bracket 375 in a manner such as bonding, clamping, and threaded connection.

The filter 374 may be configured to filter a stray light in the imaging beam obtained by imaging of the optical lens, so as to ensure better clarity of an image photographed by the camera module 30. The filter 374 includes but is not limited to a blue glass filter. For example, the filter 374 may be a reflective infrared filter or a dual-pass filter. The dual-pass filter allows both visible light and infrared light in the imaging beam to be transmitted simultaneously, or causes both visible light and light of another specific wavelength (for example, ultraviolet light) in the imaging beam to be transmitted simultaneously, or causes both infrared light and light of another specific wavelength (for example, ultraviolet light) to be transmitted simultaneously. In some other embodiments, the photosensitive component 37 may not be disposed with the filter 374 and the bracket 375.

The optical image stabilization apparatus 376 is configured to drive the second circuit board 372 to move, relative to the first circuit board 371, in the plane in which the second circuit board 372 is located, and drive the image sensor 373 and the filter 374 to move in the plane in which the second circuit board 372 is located, so as to implement OIS.

Still referring to FIG. 19, the optical image stabilization apparatus 376 includes a first coil 3761 and a first magnet 3762. The first coil 3761 is disposed on the second circuit board 372. In some embodiments, referring to FIG. 20, the first coil 3761 is disposed on the bottom surface 372b of the second circuit board 372. The first magnet 3762 is disposed on the first circuit board 371. In some embodiments, referring to FIG. 20, the first magnet 3762 is disposed on the top surface 371a of the first circuit board 371. The first coil 3761 cooperates with the first magnet 3762 to generate a Lorenz force parallel to the second circuit board 372, where the Lorenz force is used to drive the second circuit board 372, relative to the first circuit board 371, in the plane in which the second circuit board 372 is located, to implement OIS. Compared with the magnet, mass of the coil is generally relatively small. Therefore, the first coil 3761 is disposed on the second circuit board 372, which helps reduce driving load of the optical image stabilization apparatus 376, and helps reduce a volume and costs of the optical image stabilization apparatus 376.

There are four first coils 3761, and the first coils 3761 are disposed around a circumferential direction of the second circuit board 372.

Specifically, FIG. 21 is an assembly diagram of the second circuit board 372 and the optical image stabilization apparatus 376 in the photosensitive component 37 shown in FIG. 18 to FIG. 20. The second circuit board 372 is generally rectangular. In some other embodiments, the second circuit board 372 may alternatively be generally square. Four first coils 3761 in the optical image stabilization apparatus 376 are respectively disposed at four corner parts of the second circuit board 372. The corner part of the second circuit board 372 refers to an included corner part between two adjacent sides. Two adjacent sides (a side a1 and a side a2) of the second circuit board 372 are used as examples. An included angle part between the side a1 and the side a2 specifically refers to a triangle part M defined by an intersection point of of the side a1 and the side a2, a middle point o2 of the side a1, and a middle point o3 of the side a2. A relatively small quantity of electronic components are disposed at the corner part of the circuit board. Therefore, a coil is disposed at the corner part, so that utilization of the second circuit board 372 can be improved, and a setting area of the second circuit board 372 can be reduced.

There are also four first magnets 3762. The four first magnets 3762 are respectively opposite to four first coils 3761. Each first magnet 3762 includes two magnet units 3762a. The two magnet units 3762a are respectively opposite to two opposite sides of the first coil 3761, and magnetic charging directions of the two magnet units 3762a are opposite, so that two opposite sides of the first coil 3761 are subject to a Lorenz force in a same direction. The Lorenz force received by the first coil 3761 is a sum of Lorenz forces received by the two opposite sides.

In the four first coils 3761, two opposite first coils 3761 and two corresponding first magnets 3762 respectively cooperate to generate Lorenz forces F1 and F2 in a same direction, and the other two opposite first coils 3761 and two corresponding first magnets 3762 respectively cooperate to generate Lorenz forces F3 and F4 in a same direction. F1 and F2 are perpendicular to or intersect with F3 and F4.

In this way, currents with different magnitudes and different directions are introduced into the four first coils 3761 to adjust magnitudes and directions of F1, F2, F3, and F4, so that the second circuit board 372 can be driven and the image sensor 373 can be driven to move in any direction in the plane in which the second circuit board 372 is located, so as to implement OIS.

In some other embodiments, FIG. 22 is an assembly diagram of the second circuit board 372 and the optical image stabilization apparatus 376 according to still some other embodiments of this application. A difference between this embodiment and the embodiment shown in FIG. 21 lies in that: in this embodiment, four first coils 3761 are respectively disposed near middle sections of four sides of the second circuit board 372, and are respectively parallel to the sides of the second circuit board 372. In this way, it is convenient to mount and locate the four first coils 3761 on the second circuit board 372, thereby simplifying assembly of the photosensitive component 37.

In some other embodiments, a quantity of the first coils 3761 may be 6, 8, or the like, which is not specifically limited herein.

In some other embodiments, setting locations of the first coil 3761 and the first magnet 3762 may be interchangeable. That is, the first coil 3761 is disposed on the first circuit board 371, and the first magnet 3762 is disposed on the second circuit board 372.

It should be noted that the optical image stabilization apparatus 376 is configured to drive the second circuit board 372 to move, relative to the first circuit board 371, in the plane in which the second circuit board 372 is located, and drive the image sensor 373 and the filter 374 to move in the plane in which the second circuit board 372 is located, so as to implement OIS. On the premise that this objective is achieved, the optical image stabilization apparatus 376 may be in another structural form, which is not specifically limited herein.

Referring to FIG. 21 or FIG. 22, in addition to the first coil 3761 and the first magnet 3762, the optical image stabilization apparatus 376 further includes a second location detection apparatus 3763. The second location detection apparatus 3763 is configured to detect a location of the second circuit board 372 relative to the first circuit board 371, so as to implement OIS closed-loop control.

In some embodiments, still referring to FIG. 21 or FIG. 22, the second location detection apparatus 3763 includes a second Hall sensor 3763a and a fourth magnet 3763b. The second Hall sensor 3763a is disposed on the second circuit board 372. In some embodiments, the second Hall sensor 3763a is disposed on the bottom surface 372b of the second circuit board 372. The fourth magnet 3763b is disposed on the first circuit board 371. In some embodiments, the fourth magnet 3763b is disposed on the top surface 371a of the first circuit board 371. The second Hall sensor 3763a cooperates with the fourth magnet 3763b to obtain the location of the second circuit board 372 relative to the first circuit board 371.

In some other embodiments, setting locations of the second Hall sensor 3763a and the fourth magnet 3763b may also be interchangeable. That is, the second Hall sensor 3763a is disposed on the first circuit board 371, and the fourth magnet 3763b is disposed on the second circuit board 372.

An image stabilization drive chip (not shown in the figure) is further disposed on the second circuit board 372. The image stabilization drive chip is electrically connected to the first coil 3761, and the image stabilization drive chip is further electrically connected to the second Hall sensor 3763a. The image stabilization drive chip is configured to implement OIS closed-loop driving on the first coil 3761 according to a location signal detected by the second Hall sensor 3763a.

There may be one or two image stabilization drive chips. When a quantity of image stabilization drive chips is one, the image stabilization drive chip is electrically connected to four first coils 3761 at the same time. When the quantity of image stabilization drive chips is two, one of the two image stabilization drive chips is electrically connected to two opposite first coils 3761, and the other image stabilization drive chip is electrically connected to the other two opposite first coils 3761. Therefore, control complexity of the image stabilization drive chip is reduced, and costs of the image stabilization drive chip are reduced.

In some other embodiments, the camera module 30 may also form an open-loop OIS system without disposing the second location detection apparatus 3763. On the basis of this embodiment, no image stabilization drive chip needs to be disposed.

Referring back to FIG. 19 and FIG. 20, the electrical connection apparatus 377 is configured to electrically connect the second circuit board 372 to the first circuit board 371, so that image information collected by the image sensor 373 can be sequentially transmitted to the first circuit board 371 by using the second circuit board 372 and the electrical connection apparatus 374, and further transmitted by the first circuit board 371 to the main board 40 of the electronic device 100 shown in FIG. 2. Specifically, referring to FIG. 18 to FIG. 20, the photosensitive component 37 further includes an electrical connection structure 379. The electrical connection structure 379 includes but is not limited to an FPC. By using the electrical connection structure 379, the first circuit board 371 may transmit the image information to the main board 40 of the electronic device 100 shown in FIG. 2, so as to further store, process, and display the image information by using the main board 40.

In addition, the electrical connection apparatus 377 further electrically connects the image stabilization drive chip on the second circuit board 372 to the first circuit board 371. Specifically, a microprocessor is disposed on the first circuit board 371. The electrical connection apparatus 377 electrically connects the image stabilization drive chip to the first circuit board 371, and further electrically connects to the microprocessor by using the first circuit board 371. On this basis, further, the microprocessor electrically connects to the jitter detection unit 41 on the main board 40 in FIG. 3 by sequentially using the first circuit board 371 and the electrical connection structure 379.

FIG. 23 is a block diagram of an image information transmission circuit and an optical image stabilization control circuit in the photosensitive component 37 shown in FIG. 18 to FIG. 20. A signal transmission process of an image information transmission circuit is described in detail in the foregoing description, and details are not described herein again. For the optical image stabilization control circuit, a signal transmission process is specifically as follows: First, the jitter detection unit 41 transmits detected jitter information to the microprocessor. Then, the microprocessor can calculate an image stabilization compensation amount according to the obtained jitter information, and transmit the calculated image stabilization compensation amount to the image stabilization drive chip. Specifically, the microprocessor transmits the image stabilization compensation amount to the image stabilization drive chip by using an inter-integrated circuit (I2C) bus. The I2C bus is a serial bus that includes two lines: serial data (SDA) and serial clock (SCL), and can send and receive data. Finally, the image stabilization drive chip implements OIS driving according to the image stabilization compensation amount and the location information from the second Hall sensor 3763a, which can ensure accuracy of driving.

In some other embodiments, the image stabilization drive chip may alternatively be disposed on the first circuit board 371. The microprocessor may alternatively be disposed on the second circuit board 372, or may be disposed on the main board 40 of the electronic device shown in FIG. 3. The following embodiments are all described on a basis that the image stabilization drive chip is disposed on the second circuit board 372, and the microprocessor is disposed on the first circuit board 371. When the image stabilization drive chip and the microprocessor are disposed at other locations, an adaptation adjustment should be performed on a related structure, and details are not described in the following embodiments.

Referring to the foregoing description, referring to FIG. 23, the electrical connection apparatus 377 is configured to transmit the image information from the image sensor 373 and the image stabilization compensation amount from the microprocessor. On the premise that this objective is achieved, a structure of the electrical connection apparatus 377 cannot affect movement of the second circuit board 372, relative to the first circuit board 371, in the plane in which the second circuit board 372 is located. The electrical connection apparatus 377 that meets this condition may be an FPC board, or may be a structure formed by connecting a plurality of wires by using a flexible structure.

In some embodiments, referring back to FIG. 19, the electrical connection apparatus 377 includes a conductive plate 3771 and a conductive contact member 3772. A quantity of conductive plates 3771 and a quantity of conductive contact members 3772 are plural. In some other embodiments, there is one conductive plate 3771 and one conductive contact member 3772.

A plurality of conductive plates 3771 are disposed on the first circuit board 371. In some embodiments, a plurality of conductive plates 3771 are disposed on the top surface 371a of the first circuit board 371. The plurality of conductive plates 3771 are electrically connected to the first circuit board 371.

The plurality of conductive plates 3771 are metal plates fixed to the top surface 371a of the first circuit board 371. In some other embodiments, the plurality of conductive plates 3771 may alternatively be formed by a metal conductive layer (copper layer) in the first circuit board 371.

A plurality of conductive contact members 3772 are disposed on the second circuit board 372. In some embodiments, a plurality of conductive contact members 3772 are disposed on the bottom surface 372b of the second circuit board 372. The plurality of conductive contact members 3772 are electrically connected to the second circuit board 372.

The plurality of conductive contact members 3772 are electrically connected to a plurality of conductive plates 3771. Specifically, a quantity of the plurality of conductive contact members 3772 is equal to a quantity of the plurality of conductive plates 3771, and the plurality of conductive contact members 3772 are electrically connected to the plurality of conductive plates 3771 in a one-to-one manner. In some other embodiments, a quantity of the plurality of conductive contact members 3772 may also be greater than a quantity of the plurality of conductive plates 3771, and at least two conductive contact members 3772 are in electrical conduction with one conductive plate 3771.

When the second circuit board 372 moves, relative to the first circuit board 371, in the plane in which the second circuit board 372 is located, the plurality of conductive contact members 3772 separately move on a corresponding conductive plate 3771.

In this way, image information and an image stabilization compensation amount can be transmitted between the first circuit board 371 and the second circuit board 372 through cooperation between the plurality of conductive plates 3771 and the plurality of conductive contact members 3772. The electrical connection apparatus 377 does not affect movement of the second circuit board 372, relative to the first circuit board 371, in the plane in which the second circuit board 372 is located, and a volume of the electrical connection apparatus 377 is small, which helps reduce a distance between the second circuit board 372 and the first circuit board 371. In addition, when implementing the electrical connection between the two circuit boards, the electrical connection apparatus 377 supports the second circuit board 372 to a specific height from the first circuit board 371, so as to prevent the second circuit board 372 from directly contacting the first circuit board 371 and causing a short circuit.

Referring to FIG. 24 to FIG. 26, FIG. 24 is an assembly diagram of the first circuit board 371, the second circuit board 372, and the electrical connection apparatus 377 in the photosensitive component 37 shown in FIG. 18 to FIG. 20, FIG. 25 is a schematic diagram of a structure of a cross-section of the assembly diagram shown in FIG. 24 at a line C-C, and FIG. 26 is an enlarged view of a region I in the cross-section structure shown in FIG. 25. The conductive contact member 3772 includes a holder 3772a and a conductive ball 3772b. The holder 3772a is made of a conductive material. The holder 3772a has opposite top surface m1 and bottom surface m2. The holder 3772a is fixed to the second circuit board 372 by using the top surface m1, and the bottom surface m2 of the holder 3772a is back to back with the second circuit board 372. The holder 3772a is electrically connected to the second circuit board 372. In some embodiments, the holder 3772a is welded to a pad 372c of the second circuit board 372 to implement electrical conduction with the second circuit board 372. The holder 3772a is provided with a receptacle hole 3772c that runs through the bottom surface m2. The conductive ball 3772b is accommodated in the receptacle hole 3772c, and is electrically connected to the holder 3772a. A diameter of the conductive ball 3772b is greater than a diameter of an opening at one end that runs through the bottom surface m2 of the receptacle hole 3772c, a part of the conductive ball 3772b projects from the opening at one end that runs through the bottom surface m2 of the receptacle hole 3772c, and the conductive contact member 3772 is electrically connected to the conductive plate 3771 by using the part of the conductive ball 3772b. In this way, when the second circuit board 372 moves, relative to the first circuit board 371, in the plane in which the second circuit board 372 is located, conductive balls 3772b of a plurality of conductive contact members 3772 scroll on corresponding conductive plates 3771. A rolling friction pair is formed between the conductive contact member 3772 and the corresponding conductive plate 3771, and wear of the rolling friction pair is relatively small, so that service life of the electrical connection apparatus 377 can be prolonged.

On the basis of the foregoing embodiment, optionally, the receptacle hole 3772c further runs through the top surface m1 of the holder 3772a. From one end that runs through the top surface m1 to one end that runs through the bottom surface m2, an aperture of the receptacle hole 3772c gradually decreases, so that the receptacle hole 3772c is funnel-shaped. A diameter of the conductive ball 3772b is less than a diameter of an opening at one end of the receptacle hole 3772c that runs through the top surface m1. In this way, the conductive ball 3772b may be mounted in the receptacle hole 3772c by using the opening at one end of the receptacle hole 3772c that runs through the top surface m1, and stopping and limiting are performed by using the second circuit board 372. Mounting of the conductive ball 3772b is easy and efficient. In some other embodiments, the receptacle hole 3772c may not run through the top surface m1 of the holder 3772a.

In still some other embodiments, FIG. 27 is another enlarged view of a region I in a cross-sectional structure shown in FIG. 25. A difference between the electrical connection apparatus 377 in this embodiment and the electrical connection apparatus 377 in FIG. 24 to FIG. 26 is as follows: In this embodiment, the holder 3772a is made of an insulating material, and a pad 372d is disposed on the second circuit board 372. The pad 372d is opposite to the receptacle hole 3772c. The conductive ball 3772b is disposed in the receptacle hole 3772c and electrically connected to the pad 372d, so as to implement electrical connection between the conductive ball 3772b and the second circuit board 372. On this basis, holders 3772a of a plurality of conductive contact members 3772 may be connected together and formed integrally. This helps reduce difficulty and costs of making the holder 3772a.

The foregoing describes only an example in which the conductive contact member 3772 is in rolling contact with the corresponding conductive plate 3771. Certainly, this application is not limited thereto. In some other embodiments, the conductive contact member 3772 may alternatively be in sliding contact with the corresponding conductive plate 3771.

Specifically, in some examples, FIG. 28 is another enlarged view of the region I in a cross-sectional structure shown in FIG. 25. In this embodiment, the conductive contact member 3772 is hemispherical. In some other embodiments, the conductive contact member 3772 may alternatively be square, cylindrical, or the like. The conductive contact member 3772 is fixed to the second circuit board 372 and electrically connected to the second circuit board 372. In some embodiments, the conductive contact member 3772 is welded to the pad 372c of the second circuit board 372, so as to implement electrical connection between the conductive contact member 3772 and the second circuit board 372. A spherical surface of the conductive contact member 3772 is electrically connected to a corresponding conductive plate 3771. In this way, when the second circuit board 372 moves, relative to the first circuit board 371, in the plane in which the second circuit board 372 is located, the plurality of conductive contact members 3772 separately slide on a corresponding conductive plate 3771. A sliding friction pair is formed between the plurality of conductive contact members 3772 and the plurality of conductive plates 3771. A composition structure of the electrical connection apparatus 377 is simple, and costs are relatively low.

In addition to rolling contact and sliding contact, a contact manner between the conductive contact member 3772 and the corresponding conductive plate 3771 may be scrolling contact in some directions, and sliding contact in other directions. For example, the conductive contact member 3772 includes a holder and a conductive roller, and a roller-like receptacle hole is disposed on the holder. The conductive roller is housed in the receptacle hole, and a part of the conductive roller is exposed from the receptacle hole. The conductive contact member 3772 is in rolling contact with the corresponding conductive plate 3771 in one direction by using the conductive roller, and they are in sliding contact in another direction.

On the basis of various contact manners between the foregoing conductive contact member 3772 and the corresponding conductive plate 3771, a first elastic member may be disposed between the conductive plate 3771 and the first circuit board 371. The first elastic member exerts an elastic force on the conductive plate 3771 that points to the corresponding conductive contact member 3772, so that the conductive plate 3771 is in contact with the corresponding conductive contact member 3772; and/or a second elastic member is disposed between the conductive contact member 3772 and the second circuit board 372, and the second elastic member exerts an elastic force on the conductive contact member 3772 that points to the corresponding conductive plate 3771, so that the conductive contact member 3772 is in contact with the corresponding conductive plate 3771.

In this way, the first elastic member and/or the second elastic member may be used to ensure contact reliability between each conductive contact member 3772 and a corresponding conductive plate 3771.

For example, FIG. 29 is another enlarged view of a region I in the cross-sectional structure shown in FIG. 25. Compared with the electrical connection apparatus 377 in FIG. 24 to FIG. 26, a first elastic member 3701 is added to the electrical connection apparatus 377 in this embodiment, and the first elastic member 3701 is a metal dome. In some other embodiments, the first elastic member 3701 may alternatively be a coil spring, a rubber pad, or the like. The first elastic member 3701 is disposed between the conductive plate 3771 and the first circuit board 371, and the first elastic member 3701 exerts an elastic force on the conductive plate 3771 that points to the corresponding conductive contact member 3772, so that the conductive plate 3771 is in contact with the corresponding conductive contact member 3772. The metal dome has excellent elastic stability and long service life, so that reliability and service life of the electrical connection apparatus 377 can be ensured.

For another example, FIG. 30 is another enlarged view of a region I in the cross-sectional structure shown in FIG. 25. Compared with the electrical connection apparatus 377 in FIG. 24 to FIG. 26, a second elastic member 3702 is added to the electrical connection apparatus 377 in this embodiment, and the second elastic member 3702 is a metal dome. In some other embodiments, the second elastic member 3702 may alternatively be a coil spring, a rubber pad, or the like. The second elastic member 3702 is disposed between the conductive ball 3772b of the conductive contact member 3772 and the second circuit board 372, and the second elastic member 3702 exerts an elastic force on the conductive ball 3772b that points to the corresponding conductive plate 3771, so that the conductive ball 3772b is in contact with the corresponding conductive plate 3771. The metal dome has excellent elastic stability, long service life, and conductive performance. On this basis, the conductive ball 3772b is electrically connected to the second circuit board 372 by using the second elastic member 3702. In addition, the holder 3772a may be selected as an insulating material, and holders 3772a of a plurality of conductive contact members 3772 may be connected together and formed integrally. This helps reduce difficulty and costs of making the holder 3772a.

It should be noted that, in some other embodiments, setting locations of the plurality of conductive plates 3771 and the plurality of conductive contact members 3772 may also be interchangeable. That is, the plurality of conductive plates 3771 are disposed on the second circuit board 372, and the plurality of conductive contact members 3772 are disposed on the first circuit board 371.

Referring back to FIG. 19, the limiting apparatus 378 allows the second circuit board 372 to move, relative to the first circuit board 371, in the plane in which the second circuit board 372 is located, and prevents the second circuit board 372 from moving in a direction away from the first circuit board 371. In this way, OIS drive stability can be ensured. The limiting apparatus 378 that can achieve this objective has a plurality of structural forms, which are not specifically limited in this embodiment of this application.

In some embodiments, still referring to FIG. 19, the limiting apparatus 378 includes at least one third elastic member 3781. In some embodiments, there are four third elastic members 3781, and the four third elastic members 3781 are uniformly disposed around the circumference of the second circuit board 372. In some other embodiments, a quantity of the third elastic members 3781 may alternatively be 1, 2, 3, 6, 8, 10, or the like. The third elastic member 3781 exerts an elastic force on the second circuit board 372 that points to the first circuit board 371, so as to prevent the second circuit board 372 from moving in a direction away from the first circuit board 371.

In this way, when wear occurs due to relative motion between the second circuit board 372 and the first circuit board 371, under the action of the elastic force, the second circuit board 372 may be driven to move towards a direction close to the first circuit board 371 by a specific distance, so as to compensate for the wear amount, thereby extending service life of the photosensitive component 37.

Still referring to FIG. 31, FIG. 31 is a schematic diagram of a structure of a limiting apparatus 378 in the photosensitive component 37 shown in FIG. 18 to FIG. 20. The third elastic member 3781 is a spring. In some other embodiments, the third elastic member 3781 may alternatively be a coil spring, a rubber column, or the like. Structures of the four third elastic members 3781 are the same. In the following embodiment, only one third elastic member 3781 is used as an example for description.

Specifically, the third elastic member 3781 includes a first end 3781a and a second end 3781b. A part of the third elastic member 3781 that is connected between the first end 3781a and the second end 3781b can be deformed to allow the second end 3781b to move relative to the first end 3781a.

In some embodiments, the part of the third elastic member 3781 that is connected between the first end 3781a and the second end 3781b includes at least one first n-type extension section 3781c and at least one second n-type extension section 3781d. An arch direction of the first n-type extension section 3781c is a direction Fn1, and an arch direction of the second n-type extension section 3781d is a direction Fn2. The direction Fn1 is perpendicular to the direction Fn2. In some other embodiments, the direction Fn1 may alternatively intersect the direction Fn2.

FIG. 32 is an assembly diagram of the limiting apparatus 378 shown in FIG. 31 and the first circuit board 371 and the second circuit board 372. The first end 3781a of the third elastic member 3781 is bonded to the first circuit board 371 by using adhesive. In some other embodiments, the first end 3781a may alternatively be welded to the first circuit board 371. The second end 3781b is bonded to the second circuit board 372 by using adhesive. In some other embodiments, the second end 3781b may alternatively be welded to the second circuit board 372. Both the arch direction Fn1 of the first n-type extension section 3781c and the arch direction Fn2 of the second n-type extension section 3781d are parallel to the second circuit board 372. In this way, the third elastic member 3781 can allow the second circuit board 372 to move, relative to the first circuit board 371, in the plane in which the second circuit board 372 is located. In addition, a structure of the third elastic member 3781 is simple and easy to implement.

FIG. 33 is a schematic diagram of a structure of a cross-section of the camera module 30 shown in FIG. 4 at a line D-D. The first circuit board 371 in the photosensitive component 37 is fixed to the bottom surface 311b of the substrate part of the support 31 by using the top surface 371a of the first circuit board 371. The second circuit board 372, the image sensor 373, the filter 374, the bracket 375, the optical image stabilization apparatus 376, the electrical connection apparatus 377, and the limiting apparatus 378 are disposed in the accommodating groove 311d of the support 31. The light sensing surface 3731 of the image sensor 373 is opposite to the light emitting surface 34b of the optical lens 34. In this way, the structure of the camera module 30 is simple and easy to assemble. In addition, the electrical connection apparatus 377 between the first circuit board 371 and the second circuit board 372 and the image sensor 373 are stacked in a height direction of the camera module 30. This helps reduce a setting area of the first circuit board 371 and the second circuit board 372, and reduce an occupation area and a volume of the camera module 30.

FIG. 34 is a perspective sectional view of a camera module 30 according to still some other embodiments of this application. A difference between the camera module 30 shown in this embodiment and the camera module 30 shown in FIG. 33 lies in that: In this embodiment, the first circuit board 371 in the photosensitive component 37 is fixed to the bottom surface 311b of the substrate part 311 in the support 31, the second circuit board 372 is located on a side of the first circuit board 371 away from the optical lens 34, the image sensor 373, the filter 374, the bracket 375, the optical image stabilization apparatus 376, the electrical connection apparatus 377, and the limiting apparatus 378 are disposed on a side of the second circuit board 372 facing the first circuit board 371, and the electrical connection apparatus 377 is disposed on an outer periphery of the bracket 375. The light sensing surface 3731 of the image sensor 373 is opposite to the light emitting surface 34b of the optical lens 34. An optical port 371c is disposed in a region of the first circuit board 371 opposite to the light emitting surface 34b of the optical lens 34, and the optical port 371c allows light emitted by the optical lens 34 to enter the light sensing surface 3731 of the image sensor 373. In this way, the image sensor 373, the filter 374, the bracket 375, the optical image stabilization apparatus 376, the electrical connection apparatus 377, and the limiting apparatus 378 may be accommodated by using the gap between the first circuit board 371 and the second circuit board 372, thereby helping reduce the height of the camera module 30.

On the basis of the foregoing embodiment, a cover (not shown in the figure) is further fixed on a side of the first circuit board 371 away from the support 31. The cover and the first circuit board 371 enclose to form an accommodation space. The second circuit board 372, the image sensor 373, the filter 374, the bracket 375, the optical image stabilization apparatus 376, the electrical connection apparatus 377, and the limiting apparatus 378 are housed in the accommodation space. This protects the photosensitive component 37 from dust, water, and interference.

FIG. 35 is a perspective sectional view of a camera module 30 according to still some other embodiments of this application. A difference between the camera module 30 shown in this embodiment and the camera module 30 shown in FIG. 34 is as follows: In this embodiment, an avoidance port 371d is disposed on the first circuit board 371, and the optical lens 34 is located in the avoidance port 371d. In this way, the photosensitive component 37 is moved upward, and the height of the camera module 30 may be further reduced.

Based on the camera module 30 described in any one of the foregoing embodiments, FIG. 36 is an assembly diagram of a first circuit board 371 in a camera module 30, a first conductor 314 and a second conductor 315 in a support, and a first elastic structure 331, a first Hall sensor 3531, and two second coils 351 according to some embodiments of this application. The first circuit board 371 is fixed to the support. In this way, the first circuit board 371 is relatively fixed to the first conductor 314 and the second conductor 315. The first Hall sensor 3531 of the automatic focusing apparatus 35 leads out a detected focusing distance signal to the bottom of the support by using the electrical connector 3533, and is electrically connected to the first circuit board 371. Electrodes of the two second coils 351 in the automatic focusing apparatus are led out to the support by using the first elastic structure 331, and the electrodes of the two second coils 351 are further led out to the bottom of the support by using the first conductor 314 and the second conductor 315 of the support, and are electrically connected to the first circuit board 371. On this basis, a focusing drive chip may further be disposed on the first circuit board 371. The focusing drive chip is electrically connected to a lower end of the electrical connector 3533, the second end p2 of the first conductor 314, and the fourth end p4 of the second conductor 315. The focusing drive chip is configured to implement AF closed-loop driving on the two second coils 351 according to a location signal detected by the first Hall sensor 3531, so as to improve AF driving accuracy.

On the basis of the foregoing embodiments, FIG. 37 is an internal circuit block diagram of the camera module 30 shown in FIG. 4. The image information transmission circuit and the optical image stabilization control circuit are described in the foregoing description, and details are not described herein again. Optionally, the focusing drive chip is further electrically connected to the main board 40 to receive a focusing drive signal from the main board 40. In some other embodiments, the focusing drive chip may alternatively be electrically connected to the microprocessor on the first circuit board 371. The microprocessor is configured to: generate a focusing drive signal, and send the focusing drive signal to the focusing drive chip. On this basis, further, the focusing driving chip implements AF driving according to the focusing driving signal and the location information from the first Hall sensor 3531.

In the camera module 30 provided in this embodiment of this application, the first circuit board 371 is fixed to the support 31, the image sensor 373 is disposed on the second circuit board 372, and the second circuit board 372 is driven by using the optical image stabilization apparatus 376 to move, relative to the first circuit board 371, in the plane in which the second circuit board 372 is located, thereby implementing OIS. On this basis, because the circuit board of the camera module 30 includes the first circuit board 371 and the second circuit board 372, electronic components in the camera module 30 may be distributed on the first circuit board 371 and the second circuit board 372, so that an area of the second circuit board 372 used to carry the image sensor 373 can be reduced, and an occupied space when the second circuit board 372 is active can be reduced. On this basis, because the second circuit board 372 is stacked with the first circuit board 371, an occupation area and a volume of the camera module 30 may be reduced, so as to facilitate mounting in an electronic device with a limited space.

On this basis, an area of the second circuit board 372 is less than an area of the first circuit board 371, and an orthographic projection of the second circuit board 372 on the first circuit board 371 is located in the first circuit board 371. On a premise that a sum of the areas of the first circuit board 371 and the second circuit board 372 is definite, when the area of the second circuit board 372 is relatively small, an occupied space during movement is relatively small, and the occupation area of the camera module 30 can be further reduced, so as to be mounted in an electronic device with a limited space.

According to the descriptions in the foregoing embodiments, when a user takes a photo when holding the electronic device 100 and generates a jitter, the image sensor of the camera module 30 in the electronic device 100 can move in a reverse direction of the jitter direction of the electronic device 100, so as to compensate for a jitter displacement amount, thereby improving definition of a photographed picture.

In the descriptions of this specification, the described specific features, structures, materials, or characteristics may be combined in a proper manner in any one or more of the embodiments or examples.

Finally, it should be noted that the foregoing embodiments are merely intended for describing the technical solutions of this application, but not for limiting this application. Although this application is described in detail with reference to the foregoing embodiments, persons of ordinary skill in the art should understand that they may still make modifications to the technical solutions described in the foregoing embodiments or make equivalent replacements to some technical features thereof, without departing from the spirit and scope of the technical solutions of the embodiments of this application.

1. An electronic device, comprising:
a camera module, wherein the camera module comprises:
a support;
an optical lens that is located in the support and comprises a light emitting surface;
a first circuit board that is fixed to the support;
a second circuit board that is stacked with the first circuit board, wherein an image sensor is disposed on the second circuit board and comprises a light sensing surface that is opposite to the light emitting surface of the optical lens;
an electrical connection apparatus that electrically connects the second circuit board to the first circuit board; and
an optical image stabilization apparatus that is configured to drive the second circuit board to move, relative to the first circuit board, in a plane in which the second circuit board is located, so as to implement optical image stabilization.

2. The electronic device of claim 1, wherein the electrical connection apparatus comprises:
a conductive plate disposed on the first circuit board and electrically connected to the first circuit board; and
a conductive contact member disposed on the second circuit board and electrically connected to the second circuit board, wherein the conductive contact member is electrically connected to the conductive plate, and wherein the conductive contact member moves on the conductive plate when the second circuit board moves, relative to the first circuit board, in the plane in which the second circuit board is located.

3. The electronic device of claim 2, wherein the conductive contact member is not rollable relative to the second circuit board, and wherein the conductive contact member slides on the conductive plate when the second circuit board moves, relative to the first circuit board, in the plane in which the second circuit board is located.

4. The electronic device of claim 2, wherein the conductive contact member comprises a conductive ball, the conductive ball is rollable relative to the second circuit board, the conductive ball is electrically connected to the second circuit board, and the conductive contact member is electrically connected to the conductive plate by the conductive ball, and wherein the conductive ball rolls on the conductive plate when the second circuit board moves, relative to the first circuit board, in the plane in which the second circuit board is located.

5. The electronic device of claim 2, further comprising:
a first elastic member disposed between the conductive plate and the first circuit board, wherein the first elastic member exerts an elastic force on the conductive plate toward the conductive contact member, so that the conductive plate is in contact with the conductive contact member; or
a second elastic member disposed between the conductive contact member and the second circuit board, wherein the second elastic member exerts an elastic force on the conductive contact member toward the conductive plate, so that the conductive contact member is in contact with the conductive plate.

6. The electronic device of claim 1, further comprising a limiting apparatus that allows the second circuit board to move, relative to the first circuit board, in the plane in which the second circuit board is located, and prevents the second circuit board from moving in a direction away from the first circuit board.

7. The electronic device of claim 6, wherein the limiting apparatus comprises at least one third elastic member that exerts an elastic force on the second circuit board toward the first circuit board, so as to prevent the second circuit board from moving in the direction away from the first circuit board.

8. The electronic device of claim 1, wherein the second circuit board is located on a light emitting side of the optical lens, the first circuit board and the optical lens are located on a same side of the second circuit board, and the image sensor is disposed on a surface of the second circuit board close to the first circuit board.

9. The electronic device of claim 8, wherein the first circuit board is located between the second circuit board and the optical lens, and an optical port is disposed in a region on the first circuit board that is opposite to the light emitting surface of the optical lens.

10. The electronic device of claim 8, wherein an avoidance port is disposed on the first circuit board, and the optical lens is located in the avoidance port.

11. The electronic device according to of claim 1, wherein the second circuit board is located on a light emitting side of the optical lens, the first circuit board is located on a side of the second circuit board away from the optical lens, and the image sensor is disposed on a surface of the second circuit board away from the first circuit board.

12. The electronic device of claim 1, wherein an area of the second circuit board is less than an area of the first circuit board, and an orthographic projection of the second circuit board on the first circuit board is located in the first circuit board.

13. The electronic device of claim 1, wherein the optical image stabilization apparatus comprises:
a first coil disposed on the second circuit board; and
a first magnet disposed on the first circuit board, wherein the first coil cooperates with the first magnet to generate a Lorenz force parallel to the second circuit board, and the Lorenz force drives the second circuit board to move, relative to the first circuit board, in the plane in which the second circuit board is located.

14. The electronic device of claim 13, wherein the second circuit board is square or rectangular, and the first coil is disposed at a corner part of the second circuit board, and wherein the first magnet is opposite to the first coil.

15. The electronic device of claim 13, further comprising an image stabilization drive chip disposed on the second circuit board, wherein the image stabilization drive chip is electrically connected to the first coil, and the image stabilization drive chip is further electrically connected to the first circuit board by using the electrical connection apparatus.

16. A camera module, comprising:
a support;
an optical lens that is located in the support and comprises a light emitting surface;
a first circuit board that is fixed to the support;
a second circuit board, wherein the second circuit board that is stacked with the first circuit board, wherein an image sensor is disposed on the second circuit board and comprises a light sensing surface that is opposite to the light emitting surface of the optical lens;
an electrical connection apparatus that electrically connects the second circuit board to the first circuit board; and
an optical image stabilization apparatus that is configured to drive the second circuit board to move, relative to the first circuit board, in a plane in which the second circuit board is located, so as to implement optical image stabilization.

17. The camera module of claim 16, wherein the electrical connection apparatus comprises:
a conductive plate disposed on the first circuit board and electrically connected to the first circuit board; and
a conductive contact member disposed on the second circuit board and electrically connected to the second circuit board, wherein the conductive contact member is electrically connected to the conductive plate, and wherein the conductive contact member moves on the conductive plate when the second circuit board moves, relative to the first circuit board, in the plane in which the second circuit board is located.

18. The camera module of claim 17, wherein the conductive contact member is not rollable relative to the second circuit board, and wherein the conductive contact member slides on the conductive plate when the second circuit board moves, relative to the first circuit board, in the plane in which the second circuit board is located.

19. The camera module of claim 17, wherein the conductive contact member comprises a conductive ball, the conductive ball is rollable relative to the second circuit board, the conductive ball is electrically connected to the second circuit board, and the conductive contact member is electrically connected to the conductive plate by using the conductive ball and wherein the conductive ball rolls on the conductive plate when the second circuit board moves, relative to the first circuit board, in the plane in which the second circuit board is located.

20. The camera module of claim 17, further comprising:
a first elastic member disposed between the conductive plate and the first circuit board, wherein the first elastic member exerts an elastic force on the conductive plate toward the conductive contact member, so that the conductive plate is in contact with the conductive contact member; or
a second elastic member disposed between the conductive contact member and the second circuit board, wherein the second elastic member exerts an elastic force on the conductive contact member toward the conductive plate, so that the conductive contact member is in contact with the conductive plate.

21.-24. (canceled)
